(19) United States
(12) Patent Application Publication
(10) Pub. No.: US 2026/0136985 A1
(43) Pub. Date: May 14, 2026

(54) RESIDUE SMOOTHING DIELECTRIC LAYER AND METHODS OF FORMING THE SAME

(71) Applicant: Taiwan Semiconductor Manufacturing Company Limited, Hsinchu (TW)

(72) Inventors: Meng-Liang Lin, Hsinchu (TW); Chieh-Lung Lai, Taichung City (TW); Hsien-Wei Chen, Hsinchu City (TW); Kathy Wei Yan, Hsinchu (TW)

(21) Appl. No.: 18/947,370

(22) Filed: Nov. 14, 2024

(51) Int. Cl. H01L 23/31; H01L 21/56; H01L 21/683; H01L 21/768; H01L 23/00; H01L 23/522

(52) U.S. Cl. CPC H10W 74/117; H10P 72/74; H10W 20/033; H10W 20/042; H10W 20/42; H10W 74/016; H10P 72/7416; H10W 70/05; H10W 70/60; H10W 72/01365; H10W 72/07311; H10W 72/252; H10W 72/29; H10W 72/952; H10W 90/734

(57) ABSTRACT

A semiconductor structure and methods of making the same. In embodiments, the semiconductor device includes a redistribution layer. The redistribution layer includes a passivation layer and a via. Further, the semiconductor device includes a dielectric layer located above the passivation layer and a surface mount connector located above the via. In some embodiments, the surface mount connector may further be located above a portion of the dielectric layer. Additionally, the semiconductor device includes a metallic liner located between the surface mount connector and the redistribution layer.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area (i.e., footprint). In addition to smaller electronic components, improvements to the packaging of components seek to provide smaller packages that occupy less area than previous packages.

During manufacturing, the semiconductor devices undergo multiple processing steps to form the multiple layers. For example, during manufacturing a backgrind tape may be applied during a grinding and cleaning process. The removal of the backgrind tape often leaves a backgrind tape residue that may negatively impact subsequent processing steps. Mitigating the negative impacts of such residue is desired.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example schematic of a vertical cross-sectional view of a portion of a semiconductor structure with a surface mount connector according to various embodiments of the present disclosure.

FIG. 2A is a vertical cross-sectional view of a region of a portion of an intermediate semiconductor structure that includes a first carrier substrate and interposers according to various embodiments of the present disclosure.

FIG. 2B is an example schematic of a magnified vertical cross-sectional view of a layer of a redistribution layer according to various embodiments of the present disclosure.

FIG. 2C is an example schematic of a top-down view of the region of the portion of the intermediate semiconductor structure of FIG. 2A according to various embodiments of the present disclosure.

FIG. 3A is an example schematic of a cross-sectional view of a portion of an intermediate semiconductor structure after formation of redistribution-side bonding structures and first solder material portions according to various embodiments of the present disclosure.

FIG. 3B is an example schematic of a top-down view of the portion of the intermediate semiconductor structure of FIG. 3A according to various embodiments of the present disclosure.

FIG. 4A is an example schematic of a cross-sectional view of a portion of an intermediate semiconductor structure after attaching semiconductor dies according to various embodiments of the present disclosure.

FIG. 4B is an example schematic of a top-down view of the portion of the intermediate semiconductor structure of FIG. 4A according to various embodiments of the present disclosure.

FIG. 5 is an example schematic of a cross-sectional view of a portion of an intermediate semiconductor structure after formation of die-side underfill material portions according to various embodiments of the present disclosure.

FIG. 6A is an example schematic of a cross-sectional view of a portion of an intermediate semiconductor structure after formation of an epoxy molding compound (EMC) matrix according to various embodiments of the present disclosure.

FIG. 6B is a top-view of the region of the portion of the intermediate semiconductor structure of FIG. 6A according to various embodiments of the present disclosure.

FIG. 7A is an example schematic of a cross-sectional view of a portion of an intermediate semiconductor structure after attaching a second carrier substrate and detaching the first carrier substrate according to various embodiments of the present disclosure.

FIG. 7B is an example schematic of a magnified vertical cross-sectional view of etching back a portion of the redistribution layer according to various embodiments of the present disclosure.

FIG. 7C is an example schematic of a magnified vertical cross-sectional view of etching back an alternative portion of the redistribution layer according to various embodiments of the present disclosure.

FIG. 8A is an example schematic of a cross-sectional view of a portion of an intermediate semiconductor structure after forming a dielectric layer and metallic liner according to various embodiments of the present disclosure.

FIG. 8B is an example schematic of a magnified vertical cross-sectional view of depositing a dielectric material according to various embodiments of the present disclosure.

FIG. 8C is an example schematic of a magnified vertical cross-sectional view of depositing a metallic liner according to an embodiment of the present disclosure.

FIG. 9A is an example schematic of a cross-sectional view of a portion of an intermediate semiconductor structure after formation of a surface mount connector according to various embodiments of the present disclosure.

FIG. 9B is an example schematic of a magnified vertical cross-sectional view of forming a surface mount connector according to an embodiment of the present disclosure.

FIG. 9C is an example schematic of a magnified vertical cross-sectional view of etching a portion of the metallic liner according to an embodiment of the present disclosure.

FIG. 10A is an example schematic of a cross-sectional view of a portion of an intermediate semiconductor structure after applying a backgrind tape to the first exemplary structure according to various embodiments of the present disclosure.

FIG. 10B is an example schematic of a magnified vertical cross-sectional view of applying a backgrind tape surrounding the surface mount connectors according to various embodiments of the present disclosure.

FIG. 11 is an example schematic of a cross-sectional view of a portion of an intermediate semiconductor structure after a wafer thinning process of the second carrier according to various embodiments of the present disclosure.

FIG. 12A is an example schematic of a cross-sectional view of a portion of removing the backgrind tape according to various embodiments of the present disclosure.

FIG. 12B is an example schematic of a cross-sectional view of removing a backgrind tape according to various embodiments of the present disclosure.

FIG. 13 is an example schematic of a cross-sectional view of a semiconductor structure according to an embodiment of the present disclosure.

FIG. 14 is an example schematic of top view of the exemplary structure of FIG. 13 according to an embodiment of the present disclosure.

FIG. 15 is a flowchart illustrating a method of forming a semiconductor structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Ordinals such as “first,” “second,” “third,” etc. are not an inherent part of a name of any element, and are used only for the purpose of individually identifying multiple elements having the same, or similar, characteristics, and thus, different ordinals may be used for a same element across the specification and the claims. For example, a second element in the specification may be referred to as a first element in the claims.

Elements with the same reference numerals refer to the same element, and are presumed to have the same material composition and the same thickness range unless expressly indicated otherwise. As used herein, an element or a system “configured for” a function or an operation or “configured to” provide or perform a function or an operation.

During the manufacturing process of a semiconductor structure, a dry etching process is often used to thin and clean a surface. In some instances, wafer thinning involves removing a portion of the semiconductor structure to achieve a desired thickness. Wafer thinning commonly is performed by a dry etch process. Dry etching involves exposing a masked pattern on a portion of the semiconductor structure to a plasma of reactive gas such as fluorocarbons, oxygen, chlorine, boron trichloride with a mixture of nitrogen, argon, or helium. Other reactive gases may be within the scope of disclosure. Different types of dry etching include plasma etching, reactive ion etching, and deep reactive ion etching. Plasma etching involves using a plasma source to bombard the surface undergoing the dry etch process. Reactive ion etching involves accelerating ions toward the surface undergoing the dry etch process using an electric field. Deep reactive ion etching includes deep anisotropic etching of the surface undergoing the dry etch process.

During the wafer thinning process, a backgrind tape may be applied to a side of the structure opposite of the side of the structure to be thinned. The backgrind tape provides protection to the side of the structure that is not being thinned and prevents damage to elements during the thinning process. For example, a backgrind tape may protect surface mount connectors located on a backside of a redistribution layer in instances in which a carrier wafer is thinned. Additionally, the backgrind tape may shield the semiconductor structure from mechanical forces, abrasion, and contamination. Further, the backgrind tape may provide heat resistance to allow the semiconductor structure to withstand heat generated during the thinning process.

While the backgrind tape may provide protection to the semiconductor structure during the thinning process, the backgrind tape may leave a residue on the surface of the semiconductor structure once the backgrind tape is removed. This residue may result in surface roughness. During subsequent wafer processing, a chip on wafer (CoW) die singulation process may use a glue layer. In instances in which the residual backgrind tape results in the surface having a surface roughness, the residue and surface roughness may cause de-taping of the glue layer. Additionally, during CoW assembly, the surface roughness may cause underfilling delamination. Thus, process steps and structures that mitigate against the surface roughness are desired.

Embodiments of the present disclosure relate to a dielectric layer that may be formed on the surface of the semiconductor structure to provide a clean passivation surface and prevents tape residue on the surface. Various embodiments form as close to a pristine dielectric layer as possible above the passivation layer to mitigate against the issues caused and related to the surface roughness that results from backgrind tape residue, such as de-taping of a glue layer or underfill delamination.

In an embodiment, a semiconductor structure may include a redistribution layer that includes at least one passivation layer and interconnect structures formed therein. The interconnect structures may include vias and metal traces (lines). For example, to form the redistribution layer, a first passivation layer (also known as a first dielectric layer) may be deposited. The first passivation layer may be patterned and etched using photoresist materials and photolithography techniques to pattern and etch cavities in which the interconnect structures are to be formed. For example, the locations of vias in a first passivation layer may be patterned and etched and subsequently filled with a conductive material to form the vias. A second passivation layer may be deposited over the first passivation layer and via formed therein. The second passivation layer may be patterned and etched to form metal traces. This process of depositing passivation layers and forming interconnect structures therein may be repeated until the redistribution layer is complete. The semiconductor structure may further include a dielectric layer located over the first passivation layer and a surface mount connector located over the inter connect structure (e.g., via) formed in the first passivation layer of the redistribution layer. A metallic liner may be located between the surface mount connector and the redistribution layer.

An alternative embodiment is directed to a method of forming a semiconductor structure. The method may include the step of etching back a portion of a redistribution layer to expose a via. The method may further include depositing a dielectric layer over a passivation layer of the redistribution layer and depositing a metallic liner over the dielectric layer and the via. The method may also include forming a surface mount connector above the via and removing a portion of the metallic liner.

Various embodiments disclosed herein may provide various advantages and improvements. For example, various embodiments disclosed herein may provide a smooth layer for subsequent application of a glue tape over the redistribution layer. The smooth layer may be formed by the addition of a dielectric layer on the surface of the redistribution layer. In various embodiments, the dielectric layer may be formed of a material that prevents a tape residue from attaching to the dielectric layer, thereby preventing any backgrind tape residue left on the structure. By providing a clean dielectric layer post dry etching, various embodiments mitigate against the problems that may result due to backgrind tape residue such as the de-taping of a glue layer during CoW die singulation or underfill delamination.

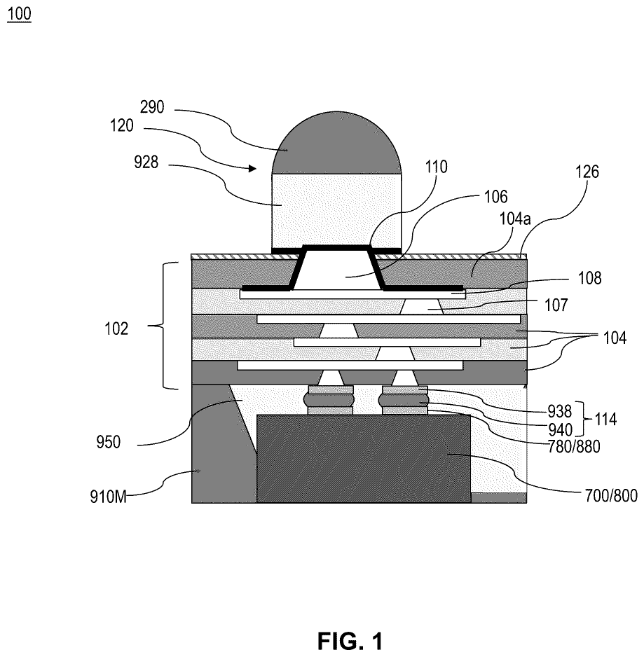

Referring now to the figures, FIG. 1 illustrates an example of a portion of a semiconductor structure 100. The semiconductor structure 100 may include a redistribution layer (RDL) 102, a semiconductor die (700, 800) connected to the RDL 102 by connectors 114, an underfill layer 950 and mold layer 910M surrounding the semiconductor die (700, 800) and connectors 114, and a surface mount connector 120. In an embodiment, the RDL 102 includes passivation layers 104 in which interconnect structures (either a via 106/107 or a metal trace 108) may be formed within each passivation layer 104, 104a. The via 106 located in the top passivation layers 104a and metal trace 108 located in a second passivation layer 104 of the RDL 102 may further have deposited thereupon a via metallic liner 110. Above the top passivation layer 104a, various embodiments disclosed herein may include a dielectric layer 126. The passivation layer 104a may be etched back to reveal the via 106 prior to depositing the dielectric layer 126 resulting in the dielectric layer 126 surrounding a top portion of the via 106. Further, the surface mount connector 120 may be located above the via 106 and optionally above a portion of the top passivation layer 104a with the dielectric layer 126 and metallic liner 110 located between the surface mount connector 120 and the RDL 102. While the RDL 102 is illustrated with five passivation layers, more or fewer passivation layers may be formed in the RDL 102.

In some embodiments, the RDL 102 may be formed in layers. Initially, a passivation layer 104a may be formed on a substrate. In some embodiments, each passivation layer 104a may be formed of a polymeric material or other appropriate dielectric material. The vias 106/107 may be formed through a variety of processes. For example, the first passivation layer 104a may be covered with a photoresist mask (not shown). Locations for cavities may be patterned in the photoresist mask using a variety of photolithography techniques. A cavity may be etched or patterned in the first passivation layer 104a of the RDL 102 using any of a variety of etching processes. Once the cavity is created, a subsequent polishing step, such as chemical mechanical polishing, optionally is performed to smooth the sides of the cavity.

In some embodiments, a via metallic liner 110 may be deposited into the cavity. The via metallic liner 110 may be deposited using chemical vapor deposition (CVD), atomic vapor deposition (AVD), or other appropriate deposition methods. In an embodiment, a conductive material may be either grown or deposited in the cavity to fill the cavity and form the via 106/107. The via 106/107 may have a trapezoidal shape, a rectangular shape, a triangular shape, or other appropriate shapes. Additionally, the conductive material may be copper, tungsten, silver, gold, or other appropriate conductive material.

After the first passivation layer 104a of the RDL 102 is formed, a subsequent passivation layer 104 may be deposited over the first passivation layer 104a that has the via 106 formed therein. Again, the subsequent passivation layer 104 material may be covered with a photoresist mask (not shown). Locations for metal traces 108 may be patterned in the photoresist mask using a variety of photolithography techniques. Cavities that may be used to form metal traces 108 may be etched into the subsequent passivation layer 104. A conductive material may be grown or deposited in the etched cavities to form metal traces 108. Alternatively, a blanket layer of conductor material may be deposited over the first passivation layer 104a. The blanket layer of conductive material may be patterned and etched to form the metal traces 108. A passivation layer 104 material may be deposited over the metal traces 108. A grinding or chemical mechanical polishing (CMP) process may be performed to planarize the passivation layer 104 material such that a top surface of the passivation layer 104 material and a top surface of the metal trace 108 are co-planer. The process of forming either vias 106 or metal traces 108 and passivation layers 104 may continue until the desired number of RDL 102 layers are created.

In some embodiments only the via 106 in the top passivation layer 104a includes a via metallic liner 110 (as shown in FIG. 1). In alternative embodiments, every via 106/107 may include a via metallic liner 110 or only a subset of vias 106/107 includes a metallic liner 110. As shown in FIG. 1, the metallic liner 110 may further be located along a side of the metal trace 108. In some embodiments, the metallic liner 110 may only be included around the vias 106, included around the vias 106 and metal traces 108, or a combination thereof.

Turning to the semiconductor die (700, 800), the semiconductor die (700, 800) may be a SoC component, an HBM component, an I/O component, or other appropriate component. The semiconductor die (700, 800) may be connected to the RDL 102 via the connectors 114. In some embodiments, the connectors 114 may be μ-bumps, conductive vias, or other appropriate connectors.

In some embodiments, the SoC component is an integrated circuit that combines multiple components onto a single chip. In some embodiments, the SoC component may include one or more of: a central processing unit (CPU), microcontroller, memory interfaces, I/O interfaces, secondary storage devices, a graphics processing unit (GPU), radio modems, coprocessors, and/or other appropriate components. In some embodiments, the SoC component may include analog, mixed-signal, and radio frequency signal processing features. In some embodiments, the SoC component may be a microcontroller-based SoC with various peripherals, a microprocessor-based SoC that includes a microprocessor, a specialized application-specific SoC designed for specific applications, or other appropriate SoC device. In some embodiments, the incorporation of multiple components (e.g., CPU, GPU, coprocessors) in the SoC component may reduce power consumption. Additionally, incorporating multiple components in the single SoC component may reduce the die area of the semiconductor device and provides tighter integration of components.

In some embodiments, the SoC component may reduce power consumption due to integrating multiple features into a single component therefore leading to higher power dissipation. Because the SoC component may multiple components, the functionality and performance of the SoC may be customized. The SoC component may also reduce the die area by incorporating multiple dies into a single component and therefore and providing improved integration of components. Additionally, the SoC component may lower latency due to placing critical components in close proximity therefore increasing performance.

In some embodiments, the semiconductor die (700, 800) is an HBM component that is a specialized computer-memory interface. The HBM component may be utilized as a 3D-stacked synchronous dynamic random-access memory (DRAM). The HBM component achieves high bandwidth by stacking multiple DRAM dies vertically. In some embodiments, the HBM component may stack multiple channels to provide wide memory bus. In some embodiments, the HBM component utilizes thru-silicon vias (TSVs) to vertically interconnect the different memory dies. Other suitable conductive materials are within the contemplated scope of disclosure. Additionally, in some embodiments, microbumps, such as copper microbumps, may be formed on top of the die to create proper electrical connections with other components. The HBM component is a memory architecture designed for HPC applications by providing higher bandwidth as compared to related memory technologies. In some embodiments, the HBM component contains a stacked design with multiple memory dies stacked vertically creating a 3D structure. In some embodiments, the HBM component may have a thickness of about 300 μm, about 400 μm, about 500 μm, about 700 μm, about 800 μm, or about 900 μm.

Due to the multiple memory dies within HBM component, in some embodiments the HBM component may achieve high bandwidth by allowing simultaneous data access process across the multiple memory dies. The HBM may also use a wide data bus to allow the HBM component to transfer data between different components (e.g., a GPU or CPU and memory) and therefore enabling high bandwidth.

In some embodiments, the semiconductor die (700, 800) is an I/O component that provides circuitry that allows for the exchange of data and signals between external devices and external devices (e.g., a monitor, speakers, a microcontroller). In some embodiments, the I/O component may include input ports for receiving data and signals and output ports used for sending data and signals. The I/O component may be a general-purpose I/O (GPIO) component that includes GPIO pins. In some embodiments, a user may dynamically change the function of the I/O component during runtime of the I/O component. In some embodiments, the I/O component has a thickness of about 300 μm, about 400 μm, about 500 μm, about 700 μm, about 800 μm, or about 900 μm.

In some embodiments, the semiconductor die (700, 800) may be coupled to the RDL 102 using a die last approach. In the die last approach, the RDL 102 is formed on a carrier wafer first. Subsequently, the semiconductor die (700, 800) is bonded on top of the RDL 102 (typically the RDL 102 may be inverted and the semiconductor die (700, 800) may be placed over the RDL 102 and electrically connected thereto) by the connector 114. Once the semiconductor die (700, 800) is attached to the RDL 102 through the connector 114, the semiconductor die (700, 800) and connectors 114 may be surrounded by an underfill layer 950. The underfill layer 950 may be injected between semiconductor die (700, 800) and fill any gap between the semiconductor die (700, 800) and RDL 102. In addition, the underfill layer 950 may fill any gaps between adjacent semiconductor die (700, 800). In turn, the semiconductor die (700, 800) and underfill layer 950 may be surrounded by the molding layer 910M. In some embodiments, the mold 910M forms a layer on top of the RDL 102 while the underfill layer 950 is formed in a portion of the mold 910M. The underfill layer 950 may generally have a rectangular, trapezoidal, triangular, or other appropriate cross-sectional shape.

The underfill layer 950 may be formed around each connector 114. In some embodiments, the underfill layer 950 may be formed of epoxy polymer and silica fillers or other combinations of materials. In some embodiments, the underfill layer 950 may provide thermal expansion matching, mechanical strength, and may fill gaps within the semiconductor structure 100 during the assembly process.

In some embodiments, the underfill layer 950 may include capillary underfill, no-flow underfill, molded underfill, or wafer-level underfill. Capillary underfill utilizes capillary flow of liquid organic resin binders mixed with inorganic fillers, such as silica, to aid in stiffening the material and reducing the coefficient of thermal expansion. No-flow underfill is applied directly to the semiconductor structure 100 without flowing. No-flow underfill may provide better control over the underfill process and reduce the risk of voids or incomplete coverage. Molded underfill is pre-molded to a specific shape. The molded underfill undergoes a curing process to ensure proper bonding after being placed on the semiconductor device. Wafer-level underfill is applied to the entire semiconductor device before dicing using specialized equipment and processes. Any known underfill material application method may be used, which may be, for example, the capillary underfill method, the molded underfill method, or the printed underfill method.

In some embodiments, the underfill layer 950 may be formed of an epoxy polymer or other appropriate composite material. The underfill layer 950 may provide mechanical support and structural reinforcement to the semiconductor 100 therefore protecting the connectors 114. In some embodiments, the underfill layer 950 may also dissipate heat produced by the semiconductor dies (700,800) due to the large surface area of the underfill layer 950. The underfill layer 950 may also provide stress relief by providing a compliant layer that reduces mechanical stress in instances in which the semiconductor die (700, 800) or connectors 114 expand or contract during temperature cycling. The underfill layer 950 may further prevent moisture ingress by encapsulating the connectors 114 and protecting the connections from moisture and contaminates resulting in long-term reliability. Additionally, the underfill layer 950 may improve the durability of the semiconductor structure 100 by improving the robustness and preventing detachment of the components by providing a protective layer surrounding the components.

The mold 910M may be applied in direct contact with the RDL 102. In some embodiments, the mold 910M surrounds the underfill layer 950 material. The mold 910M may be formed of organic resins, such as epoxy resin, fillers, catalysts, and other appropriate materials. The mold 910M is located adjacent to the underfill layer 950 to form an outside wall. The mold 910M may encapsulate the semiconductor die (700, 800) and underfill layer 950 thereby protecting the semiconductor device from external factors such as impact, pressure, moisture, heat, and UV rays. The mold 910M may also maintain the electric insulating properties of the semiconductor structure 100 by preventing contact between the semiconductor die (700, 800) and the environment. For example, the mold 910M may prevent short-circuits due to unwanted interactions. Additionally, the mold 910M may provide the semiconductor structure 100 with proper and easy mounting.

The mold 910M may include an epoxy-containing compound that may be hardened (i.e., cured) to provide a dielectric material portion having sufficient stiffness and mechanical strength. The mold 910M may include epoxy resin, hardener, silica (as a filler material), and other additives. The mold 910M may be provided in a liquid form or in a solid form depending on the viscosity and flowability. Liquid molding compound provides better handling, good flowability, less voids, better fill, and less flow marks. Solid molding compound provides less cure shrinkage, better stand-off, and less die drift. A high filler content (such as 85% in weight) within a molding compound may shorten the time in mold, lower the mold shrinkage, and reduce the mold warpage. Uniform filler size distribution in the molding compound may reduce flow marks and may enhance flowability. The curing temperature of the molding compound may be in a range from 125° C. to 150° C.

The mold 910M may be cured at a curing temperature to form a matrix that laterally surrounds the underfill 950 and portions of the semiconductor die (700, 800). The molding compound matrix includes a plurality of molding compound die frames that are interconnected to one another. The Young's modulus of pure epoxy is about 3.35 GPa, and Young's modulus of the mold 910M may be higher than Young's modulus of pure epoxy by adding additives. Young's modulus of the mold 910M may be greater than 3.5 GPa. The Young's modulus of the mold 910M may provide sufficient stiffness to mitigate against cracking and stress due to thermal expansion. In some embodiments, suitable alternative molding materials may be used for the mold 910M.

The mold 910M may further encapsulate the semiconductor die (700, 800) to protect the semiconductor die (700, 800) from damage. For example, the mold 910M may protect the device from mechanical distortion, moisture migration, chemical damage, ultraviolet radiation and heat. In other words, the mold 910M protects semiconductor die (700, 800) within the device from external damage. Additionally, the mold 910M may dissipate the heat produced by components further providing thermal management.

In an embodiment, a dielectric layer 126 may be deposited above the top passivation layer 104 in the RDL 102. The dielectric layer 126 may also be referred to as a pristine passivation layer or a clean passivation layer. The dielectric layer 126 provides a smooth surface above the RDL 102 to eliminate potential issues arising from tape residue such as de-taping of a glue layer or underfill delamination. The dielectric layer 126 is deposited using CVD, AVD, or other appropriate deposition methods. In an embodiment, the dielectric layer 126 is deposited using a low temperature CVD method. By using a low temperature CVD method, the dielectric layer 126 has a fine inorganic grain structure compared to other deposition methods.

As illustrated in FIG. 1, the surface mount connector 120 is a C4 bump connector. The C4 bump 120 may include a pad 928 and a solder material portions 290. In some embodiments, the bonding pads 928 and the solder material portions 290 may be formed of a solder alloy such as a tin-lead alloy.

The C4 bump 120 may allow for more compact package design by attaching a chip directly to the semiconductor structure 100 reducing the use of wire bonds and external connections resulting in smaller devices. Further, the C4 bump 120 may provide high-density interconnections by serving as bridges between components forming reliable and dense electrical connections. The high-density arraignment may improve signal integrity and performance. Even further, the C4 bumps 120 may provide a direct attachment between the semiconductor structure 100 and other components/devices therefore enhancing heat dissipation because heat can flow more efficiently through the bumps and reduce the risk of overheating. Additionally, the C4 bumps 120 may provide shorter signal paths which leads to faster data transfer and improved overall performance.

In some embodiments, the connectors 120 may be other types of connectors 120, such as ball grid arrays, ceramic pin grid arrays, land grid arrays, quad flat pack arrays, or other appropriate connectors.

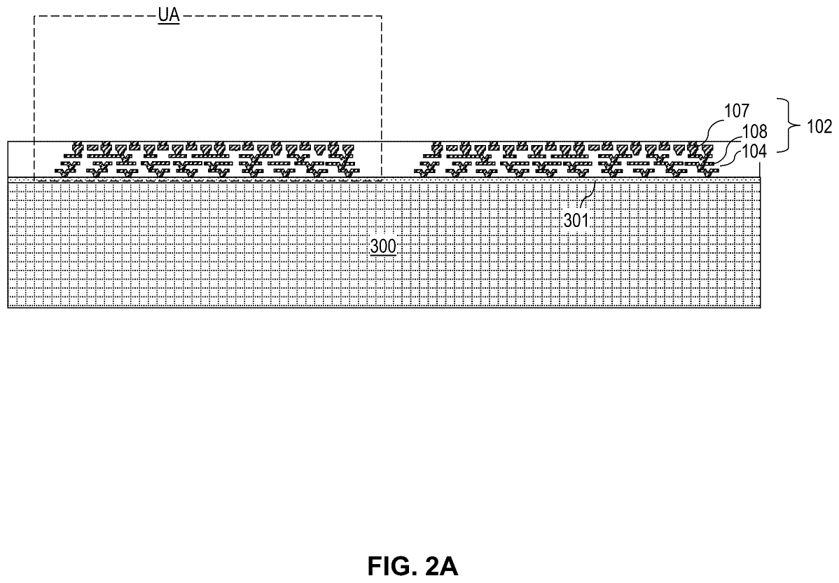

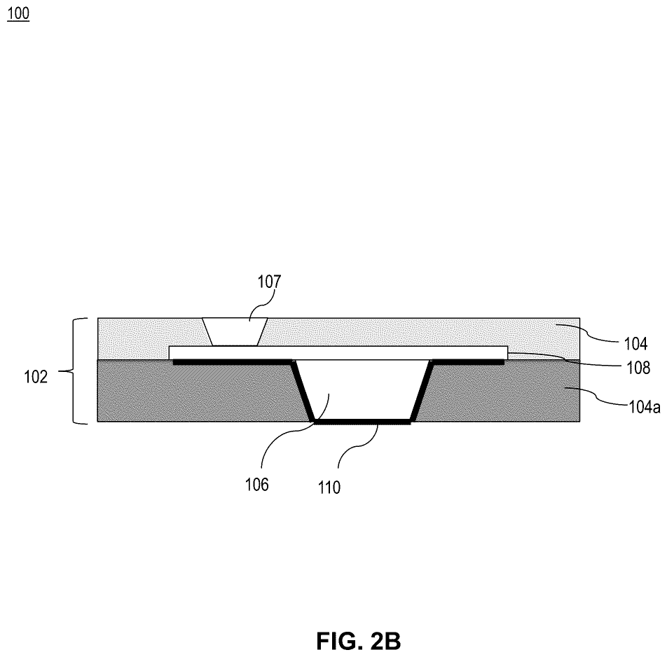

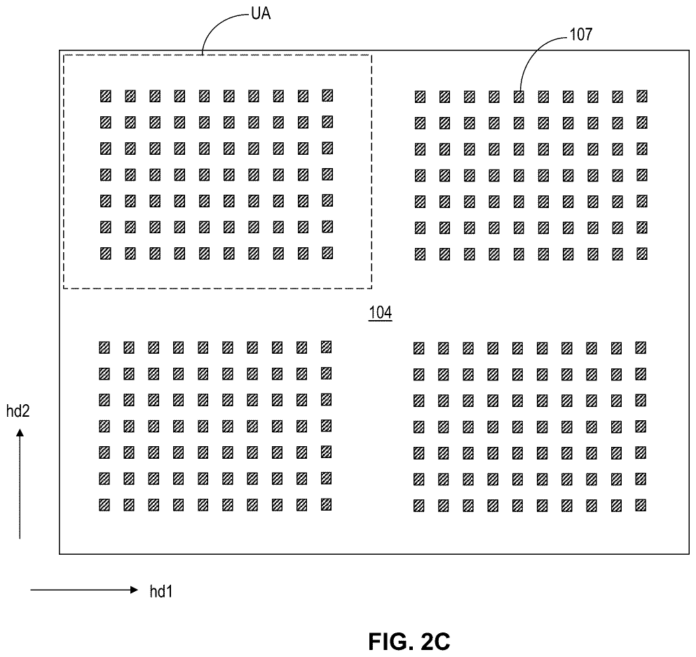

Turning now to FIGS. 2A through 12 which illustrate an example of forming the semiconductor structure 100 shown in FIG. 1. Referring to FIGS. 2A-2C, a first exemplary structure according to an embodiment of the present disclosure may include a first carrier substrate 300 and RDL 102 formed on a front side surface of the first carrier substrate 300. The first carrier substrate 300 may include an optically transparent substrate such as a glass substrate or a sapphire substrate. The diameter of the first carrier substrate 300 may be in a range from 150 mm to 290 mm, although lesser and greater diameters may be used. In addition, the thickness of the first carrier substrate 300 may be in a range from 500 microns to 2,000 microns, although lesser and greater thicknesses may also be used. Alternatively, the first carrier substrate 300 may be provided in a rectangular panel format. The dimensions of the first carrier in such alternative embodiments may be substantially the same.

A first adhesive layer 301 may be applied to the front-side surface of the first carrier substrate 300. In one embodiment, the first adhesive layer 301 may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 301 may include a thermally decomposing adhesive material. For example, the first adhesive layer 301 may include an acrylic pressure-sensitive adhesive that decomposes at an elevated temperature. The debonding temperature of the thermally decomposing adhesive material may be in a range from 150 degrees to 200 degrees Celsius.

RDL 102 may be formed over the first adhesive layer 301. Specifically, an RDL 102 may be formed within each unit area UA, which is the area of a repetition unit that may be repeated in a two-dimensional array over the first carrier substrate 300. RDL 102 may include redistribution dielectric layers 104 and vias 106/107 and metal traces 108. The redistribution dielectric layers 104 include a respective dielectric polymer material such as polyimide (PI), benzocyclobutene (BCB), or polybenzobisoxazole (PBO). Other suitable materials may be within the contemplated scope of disclosure. Each redistribution dielectric layer 104 may be formed by spin coating and drying of the respective dielectric polymer material. The thickness of each redistribution dielectric layer 104 may be in a range from 2 microns to 40 microns, such as from 4 microns to 20 microns. Each redistribution dielectric layer 104 may be patterned, for example, by applying and patterning a respective photoresist layer thereabove, and by transferring the pattern in the photoresist layer into the redistribution dielectric layer 104 using an etch process such as an anisotropic etch process. The photoresist layer may be subsequently removed, for example, by ashing.

Each of the vias 106/107 and metal traces 108 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 400 nm, and the copper seed layer may have a thickness in a range from 100 nm to 500 nm. The metallic fill material for the vias 106/107 and metal traces 108 may include copper, nickel, or copper and nickel. Other suitable metallic fill materials are within the contemplated scope of disclosure. The thickness of the metallic fill material that is deposited for each via 106/107 and metal trace 108 may be in a range from 2 microns to 40 microns, such as from 4 microns to 10 microns, although lesser or greater thicknesses may also be used. The total number of levels of wiring in RDL 102 (i.e., the levels of the vias 106/107 and metal traces 108) may be in a range from 1 to 10.

FIG. 2B illustrates an example of forming a portion of the RDL 102. As described above, a cavity may be patterned and etched in a first passivation layer 104a. In some embodiments, a metallic liner 110 is deposited in the cavity. In some embodiments, the metallic liner 110 is formed of a copper seed with a titanium adhesion layer. A conductive material may be grown or deposited in the cavity to form the via 106 and metal trace 108. The conductive material may be copper, silver, gold, tungsten, or other appropriate conductive material. In some embodiments, the etching of a cavity and filling with metallic materials results in a via 106 having a trapezoidal shape. Further passivation layers 104 may be deposited over the first passivation layer 104a and patterned and etched to form vias 107.

FIG. 2C illustrates a periodic two-dimensional array (such as a rectangular array) of RDL 102 may be formed over the first carrier substrate 300. RDL 102 may be formed within a unit area UA. In one embodiment, the two-dimensional array of RDL 102 may be a rectangular periodic two-dimensional array of RDL 102 having a first periodicity along a first horizontal direction hd1 and having a second periodicity along a second horizontal direction hd2 that is perpendicular to the first horizontal direction hd1.

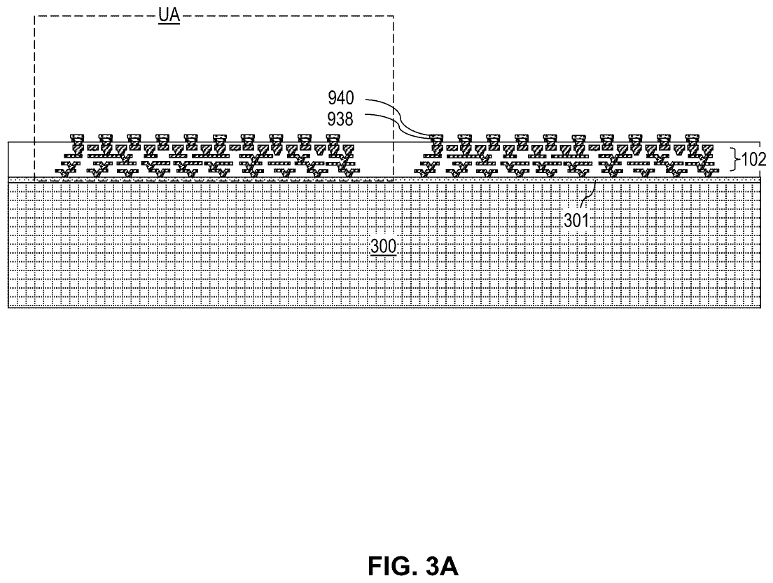

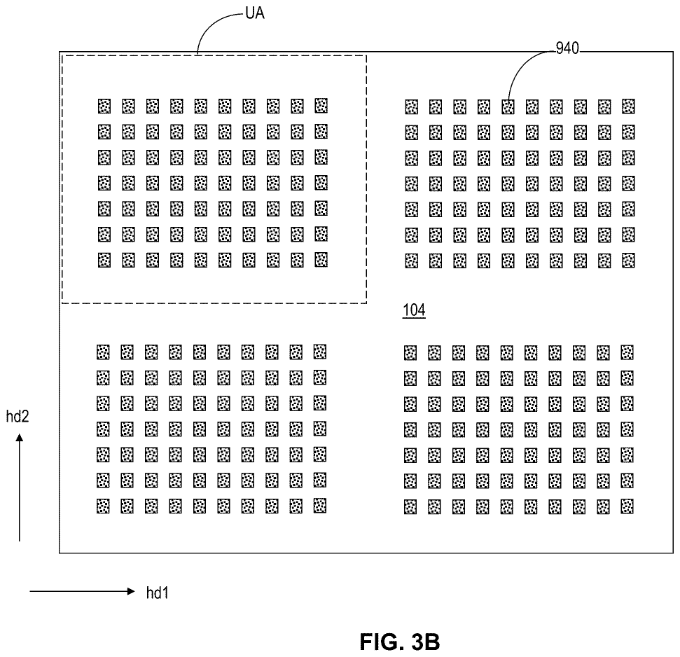

Referring to FIGS. 3A and 3B, at least one metallic material 938 and a first solder material 940 may be sequentially deposited over the front-side surface of the RDL 102 to form the connectors 114. The at least one metallic material 938 comprises a material that may be used for metallic bumps, such as copper. The thickness of the at least one metallic material may be in a range from 5 microns to 60 microns, such as from 10 microns to 30 microns, although lesser and greater thicknesses may also be used. The first solder material 940 may comprise a solder material suitable for C2 bonding, i.e., for microbump bonding. The thickness of the first solder material may be in a range from 2 microns to 30 microns, such as from 4 microns to 15 microns, although lesser and greater thicknesses may also be used.

The first solder material 940 and the at least one metallic material 938 may be patterned into discrete arrays of first solder material portions 940 and arrays of metal bonding structures, which are herein referred to as arrays of redistribution-side bonding structures 938. Each array of redistribution-side bonding structures 938 is formed within a respective unit area UA. Each array of first solder material portions 940 is formed within a respective unit area UA. Each first solder material portion 940 may have a same horizontal cross-sectional shape as an underlying redistribution-side bonding structures 938.

In one embodiment, the redistribution-side bonding structures 938 may include, and/or may consist essentially of, copper or a copper-containing alloy. Other suitable materials are within the contemplated scope of disclosure. The thickness of the redistribution-side bonding structures 938 may be in a range from 5 microns to 60 microns, although lesser or greater thicknesses may also be used. The redistribution-side bonding structures 938 may have horizontal cross-sectional shapes of rectangles, rounded rectangles, circles, regular polygons, irregular polygons, or any other two-dimensional curvilinear shape having a closed periphery. In one embodiment, redistribution-side bonding structures 938 may be configured for microbump bonding (i.e., C2 bonding), and may have a thickness in a range from 10 microns to 30 microns, although lesser or greater thicknesses may also be used. In this embodiment, each array of redistribution-side bonding structures 938 may be formed as an array of microbumps (such as copper pillars) having a lateral dimension in a range from 10 microns to 25 microns, and having a pitch in a range from 20 microns to 50 microns.

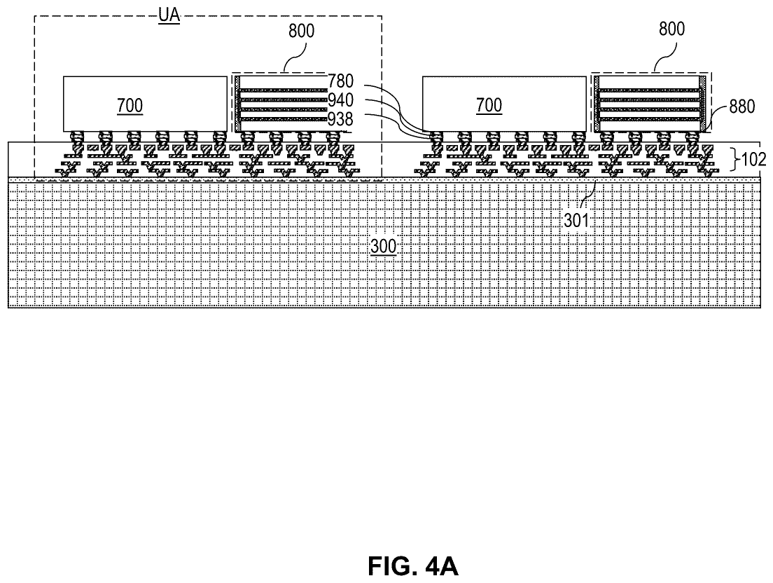

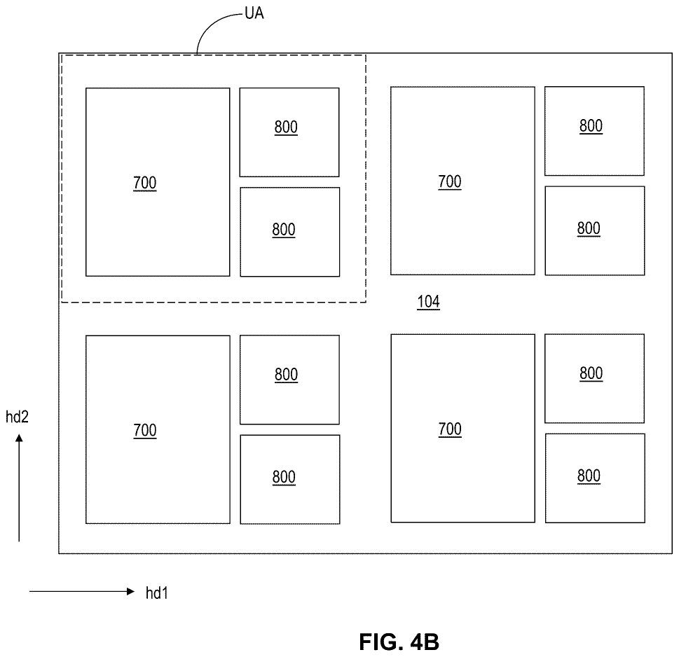

Referring to FIGS. 4A and 4B, a set of at least one semiconductor die (700, 800) may be bonded to RDL 102 through connectors 114. In one embodiment, the RDL 102 may be arranged as a two-dimensional periodic array, and multiple sets of at least one semiconductor die (700, 800) may be bonded to the RDL 102 as a two-dimensional periodic rectangular array of sets of the at least one semiconductor die (700, 800). Each set of at least one semiconductor die (700, 800) includes at least one semiconductor die. Each set of at least one semiconductor die (700, 800) may include any set of at least one semiconductor die known in the art. In one embodiment, each set of at least one semiconductor die (700, 800) may comprise a plurality of semiconductor dies (700, 800). For example, each set of at least one semiconductor die (700, 800) may include at least one system-on-chip (SoC) die 700 and/or at least one memory die 800. Each SoC die 700 may comprise an application processor die, a central processing unit die, or a graphic processing unit die. In one embodiment, the at least one memory die 800 may comprise a high bandwidth memory (HBM) die that includes a vertical stack of static random access memory dies. In one embodiment, the at least one semiconductor die (700, 800) may include at least one system-on-chip (SoC) die and a high bandwidth memory (HBM) die including a vertical stack of static random access memory (SRAM) dies that are interconnected to one another through microbumps and are laterally surrounded by an epoxy molding material enclosure frame.

Each semiconductor die (700, 800) may comprise a respective array of die-side bonding structures (780, 880). For example, each SoC die 700 may comprise an array of SoC metal bonding structures 780, and each memory die 800 may comprise an array of memory-die metal bonding structures 880. Each of the semiconductor dies (700, 800) may be positioned in a face-down position such that die-side bonding structures (780, 880) face the first solder material portions 940. Each set of at least one semiconductor die (700, 800) may be placed within a respective unit area UA. Placement of the semiconductor dies (700, 800) may be performed using a pick and place apparatus such that each of the die-side bonding structures (780, 880) may be placed on a top surface of a respective one of the first solder material portions 940 located in the connectors 114.

The connectors 114 include redistribution-side bonding structures 938 and solder material portions 940. Additionally, the semiconductor die (700, 800) includes a respective set of die-side bonding structures (780, 880). The at least one semiconductor die (700, 800) may be bonded to the RDL 102 through the connectors 114 using first solder material portions 940 that are bonded to a respective redistribution-side bonding structure 938 and to a respective one of the die-side bonding structures (780, 880). Each set of at least one semiconductor die (700, 800) may be attached to a respective RDL 102 through a respective set of first solder material portions 940.

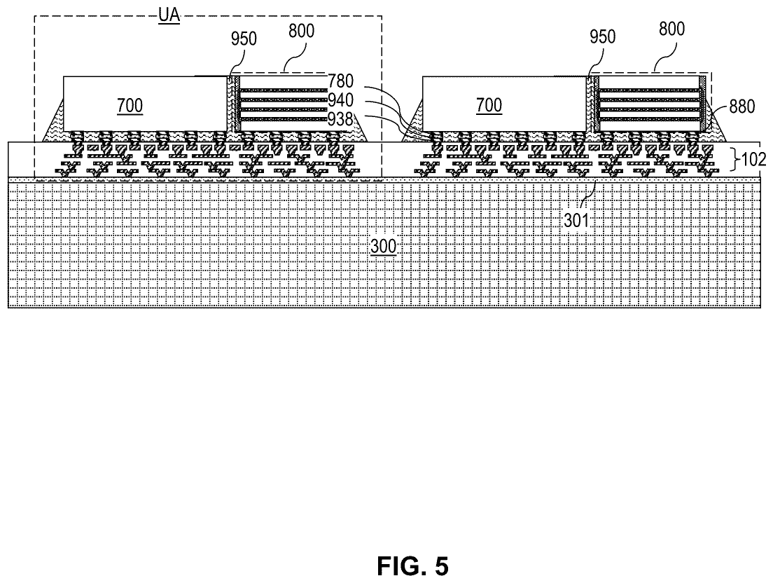

Referring to FIG. 5, a die-side underfill material may be applied into each gap between the RDL 102 and sets of at least one semiconductor die (700, 800) that are bonded to the RDL 102. The die-side underfill material may comprise any underfill material known in the art. A die-side underfill material portion 950 may be formed within each unit area UA between an RDL 102 and an overlying set of at least one semiconductor die (700, 800). The die-side underfill material portions 950 may be formed by injecting the die-side underfill material around a respective array of first solder material portions 940 in a respective unit area UA. Any known underfill material application method may be used, which may be, for example, the capillary underfill method, the molded underfill method, or the printed underfill method.

Within each unit area UA, a die-side underfill material portion 950 may laterally surround, and contact, each of the first solder material portions 940 within the unit area UA. The die-side underfill material portion 950 may be formed around, and contact, the first solder material portions 940, the redistribution-side bonding structures 938, and the die-side bonding structures (780, 880) in the unit area UA.

RDL 102 in a unit area UA comprises redistribution-side bonding structures 938. At least one semiconductor die (700, 800) comprising a respective set of die-side bonding structures (780, 880) is attached to the redistribution-side bonding structures 938 through a respective set of first solder material portions 940 within each unit area UA. Within each unit area UA, a die-side underfill material portion 950 laterally surrounds the redistribution-side bonding structures 938 and the die-side bonding structures (780, 880) of the at least one semiconductor die (700, 800).

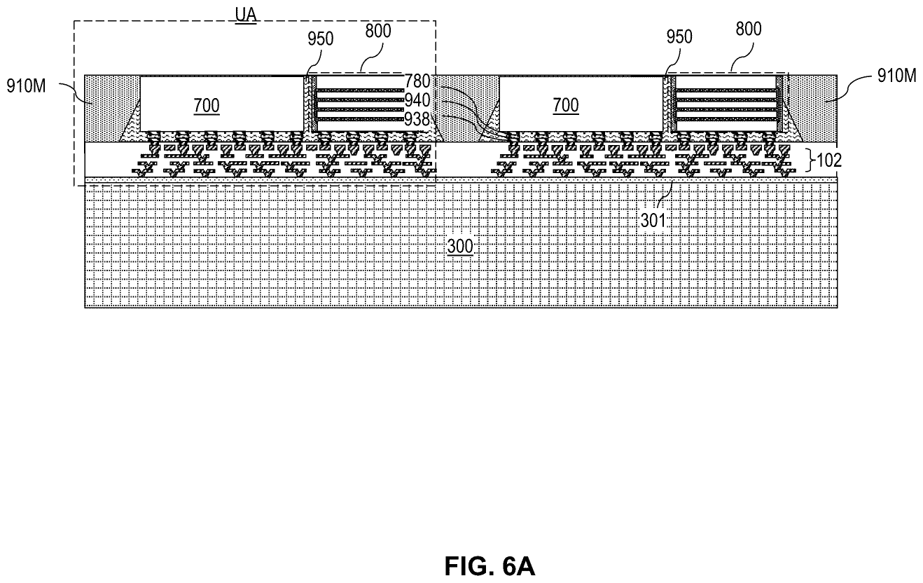

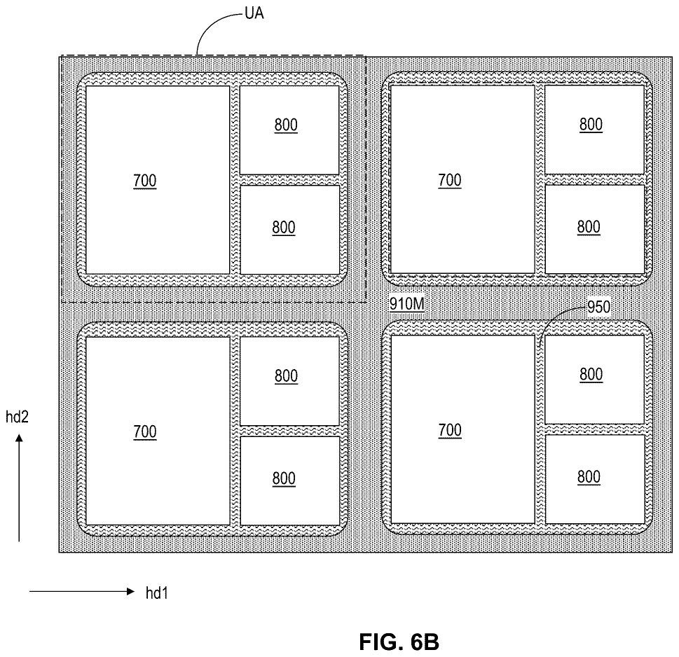

Referring to FIGS. 6A and 6B, an epoxy molding compound (EMC) may be applied to the gaps between contiguous assemblies of a respective set of semiconductor dies (700, 800) and a die-side underfill material portion 950.

The EMC may include an epoxy-containing compound that may be hardened (i.e., cured) to provide a dielectric material portion having sufficient stiffness and mechanical strength. The EMC may include epoxy resin, hardener, silica (as a filler material), and other additives. The EMC may be provided in a liquid form or in a solid form depending on the viscosity and flowability. Liquid EMC provides better handling, good flowability, less voids, better fill, and less flow marks. Solid EMC provides less cure shrinkage, better stand-off, and less die drift. A high filler content (such as 85% in weight) within an EMC may shorten the time in mold, lower the mold shrinkage, and reduce the mold warpage. Uniform filler size distribution in the EMC may reduce flow marks, and may enhance flowability. The curing temperature of the EMC may be lower than the release (debonding) temperature of the first adhesive layer 301 in embodiments in which the adhesive layer includes a thermally debonding material. For example, the curing temperature of the EMC may be in a range from 125° C. to 150° C.

The EMC may be cured at a curing temperature to form an EMC matrix 910M that laterally surrounds and embeds each assembly of a set of semiconductor dies (700, 800) and a die-side underfill material portion 950. The EMC matrix 910M includes a plurality of epoxy molding compound (EMC) die frames that may be laterally adjoined to one another. Each EMC die frame is a portion of the EMC matrix 910M that is located within a respective unit area UA. Thus, each EMC die frame laterally surrounds and embeds a respective a set of semiconductor dies (700, 800) and a respective die-side underfill material portion 950. Young's modulus of pure epoxy is about 3.35 GPa, and Young's modulus of the EMC may be higher than Young's modulus of pure epoxy by adding additives. Young's modulus of EMC may be greater than 3.5 GPa.

Portions of the EMC matrix 910M that overlies the horizontal plane including the top surfaces of the semiconductor dies (700, 800) may be removed by a planarization process. For example, the portions of the EMC matrix 910M that overlies the horizontal plane may be removed using a chemical mechanical planarization (CMP). The combination of the remaining portion of the EMC matrix 910M, the semiconductor dies (700, 800), the die-side underfill material portions 950, and the two-dimensional array of RDL 102. Each portion of the EMC matrix 910M located within a unit area UA constitutes an EMC die frame.

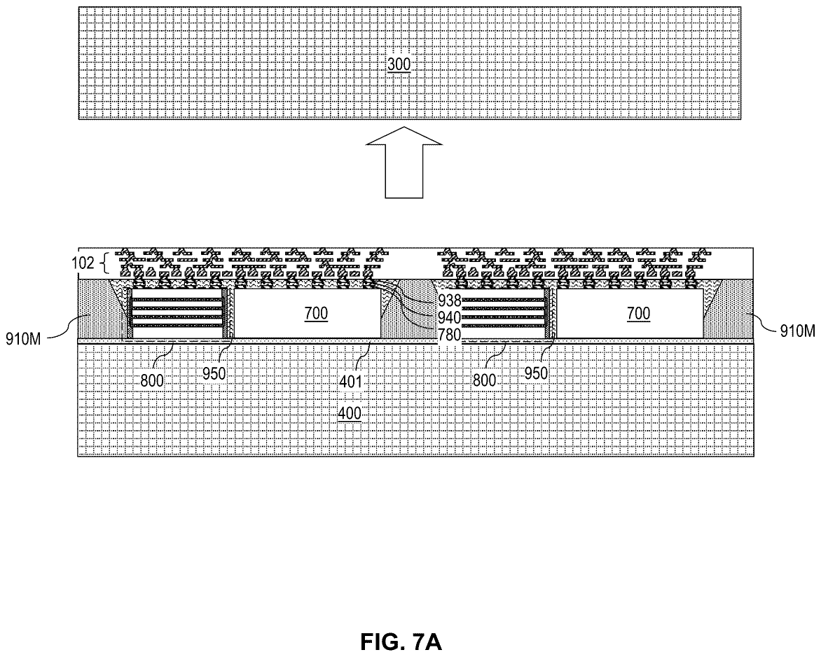

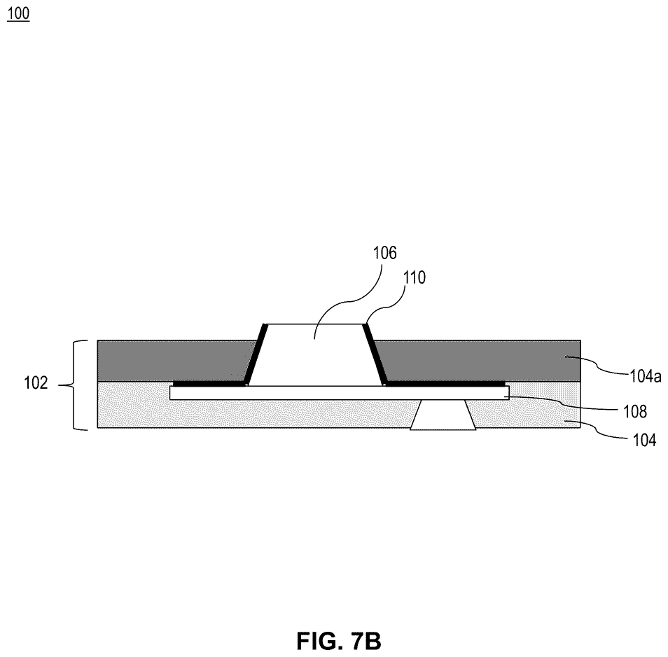

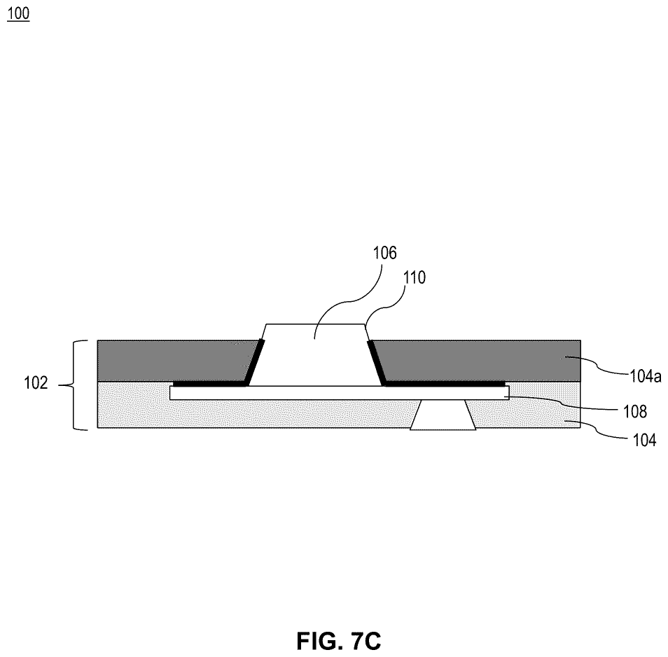

Referring to FIG. 7A, a second adhesive layer 401 may be applied to the physically exposed planar surface of the physically exposed surfaces of the EMC matrix 910M, the semiconductor dies (700, 800), and the die-side underfill material portions 950. In one embodiment, the second adhesive layer 401 may comprise a same material as, or may comprise a different material from, the material of the first adhesive layer 301. In embodiments in which the first adhesive layer 301 comprises a thermally decomposing adhesive material, the second adhesive layer 401 may comprise another thermally decomposing adhesive material that decomposes at a higher temperature, or may comprise a light-to-heat conversion material.

A second carrier substrate 400 may be attached to the second adhesive layer 401. The second carrier substrate 400 may be attached to the opposite side of the first carrier substrate 300. Generally, the second carrier substrate 400 may comprise any material that may be used for the first carrier substrate 300. The thickness of the second carrier substrate 400 may be in a range from 500 microns to 2,000 microns, although lesser and greater thicknesses may also be used.

The first adhesive layer 301 may be decomposed by ultraviolet radiation or by a thermal anneal at a debonding temperature. In embodiments in which the first carrier substrate 300 includes an optically transparent material and the first adhesive layer 301 includes an LTHC layer, the first adhesive layer 301 may be decomposed by irradiating ultraviolet light through the transparent carrier substrate. The LTHC layer may be absorb the ultraviolet radiation and generate heat, which decomposes the material of the LTHC layer and cause the transparent first carrier substrate 300 to be detached. In embodiments in which the first adhesive layer 301 includes a thermally decomposing adhesive material, a thermal anneal process at a debonding temperature may be performed to detach the first carrier substrate 300 from the RDL 102.

Turning to FIG. 7B, in an embodiment, the top passivation layer 104a and a top portion of the metallic liner 110 may be etched back to reveal the top surface (previously bottom surface but now top surface) of the via 106. In some embodiments, the metallic liner 110 may be removed from the top of the via 106 or from the top of the via 106 and partially on the sides of the via 110 as well. In some embodiments, the passivation layer 104a may be etched back beyond the via 106 such that the top of the via 106 is above a remaining top surface of the passivation layer 104a.

The etch back process may be a dry etching process or a wet etching process. A wet etching process includes applying liquid chemicals to the surface to remove the material. The wet etching process may include electrochemical electrolysis, chemical corrosion, or mechanical polishing. A dry etching process may include using plasma or reactive gases. Examples of dry etching include ion beam etching, plasma etching, and reactive ion etching. Plasma etching includes radiating ions, such as argon, onto a surface to cause the material to be removed. Plasma etching includes a chemical etch process used for isotropic removal of an entire layer. Reactive ion etching includes selectively etching the surface uniformly.

In some embodiments, the etch back process may further remove the metallic liner 110 from the top of the via 106 and portions of the sides of the via 106, as shown in FIG. 7C. As a result, the metallic liner 110 may be co-planar with the top passivation layer 104a.

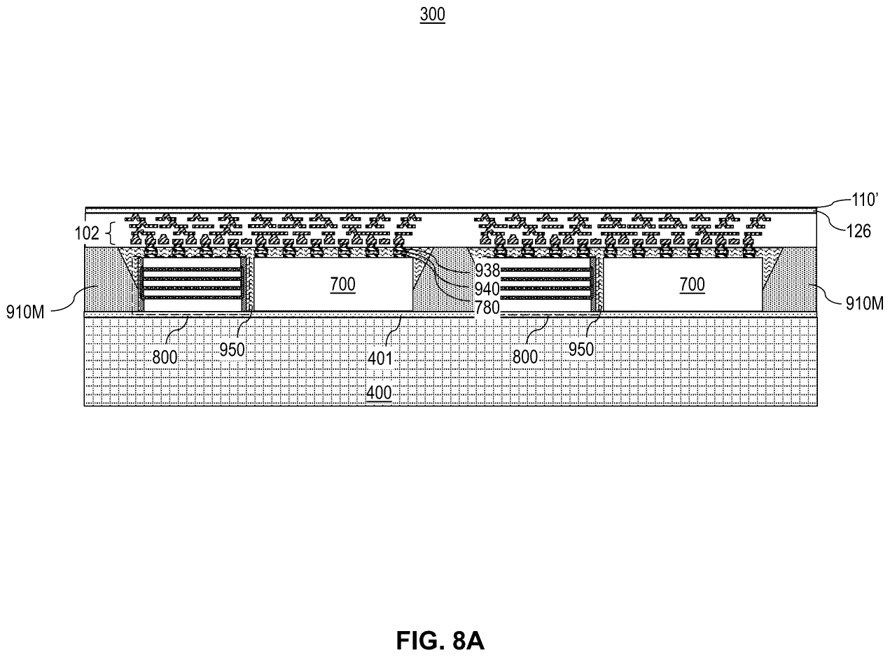

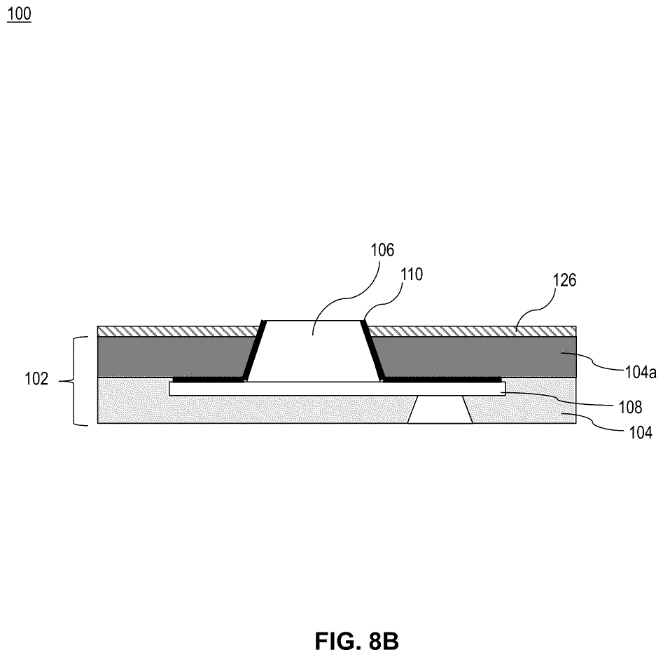

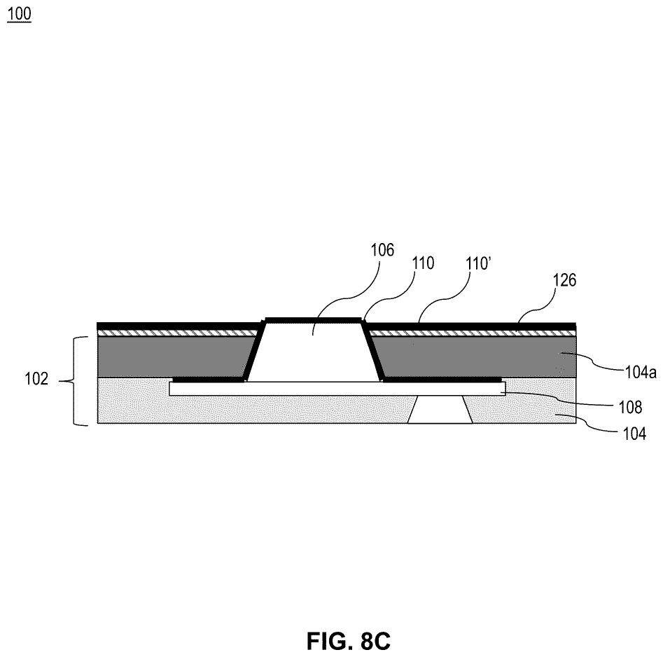

Referring to FIG. 8A, a dielectric layer 126 and a metallic liner 110′ may be formed above the RDL 102. In some embodiments, the dielectric layer 126 creates a pristine, smooth dielectric layer 126 above the RDL 102.

With reference to FIG. 8B, a dielectric layer 126 may be deposited over the remaining first passivation layer 104a. The dielectric layer 126 may provide a pristine, clean layer above the top passivation layer 104 providing a smooth surface above the passivation layer 104 after the etch back process. Additionally, the dielectric layer 126 may be formed of a material that prevents a tape residue from attaching to a top surface of the dielectric layer. For example, the dielectric layer 126 may be formed of silicon oxynitride, silicon nitride, or other appropriate dielectric materials.

In some embodiments, the dielectric layer 126 has a thickness of between about 0.01 μm to about 5 μm, or about 0.05 μm to about 3 μm. In an embodiment, the dielectric layer 126 has a thickness to provide a substantially smooth surface.

The dielectric layer 126 may be deposited using CVD, AVD, physical vapor deposition (PVD), or other appropriate deposition methods. In an embodiment, the dielectric layer 104 is deposited using a low temperature CVD method. The low temperature CVD process is a vacuum-based thin film deposition process that occurs at temperatures between about 350° C. and about 450° C. The low temperature CVD may be a plasma-enhanced CVD. Other low temperature deposition methods include thermal CVD, atomic layer deposition (ALD), metal-organic chemical vapor deposition (MOCVD) or other appropriate low temperature deposition methods.

Low temperature deposition methods, such as low temperature CVD, may enable scalability and compatibility by integration 2D materials on surfaces and overcoming limitations of high thermal budgets caused by transferring 2D films onto substrates. Further, low temperature deposition methods may reduce stress by operating at lower temperatures and minimizing stress between thin film layers with different thermal expansion coefficients resulting in high-efficiency electrical performance and strong bonding. Additionally, low temperature CVD ay achieve a fine inorganic grain structure on the surface and minimize surface roughness.

Referring to FIG. 8C, in some embodiments, a metallic liner 110′ may be deposited over the dielectric layer 126 and the exposed via 106. In some embodiments, the metallic liner 110′ may be deposited using CVD, AVD, ALD, or other appropriate deposition methods. In some embodiments, the metallic liner 110′ may be formed of a copper metallic liner with a titanium adhesion layer. Other suitable metallic liner materials are within the contemplated scope of disclosure.

The metallic liner 110′ may ensure strong adhesion between the via 106 and the surface mount connector 120 and a barrier to prevent diffusion between the via 106 and solder in the surface mount connector 120. Further, the metallic liner 110′ may provide a conductive path for electrical signals thereby improving signaling and power utilization. Additionally, the metallic liner 110′ may create a smooth film that may be electroplated and allow successful electro-deposition.

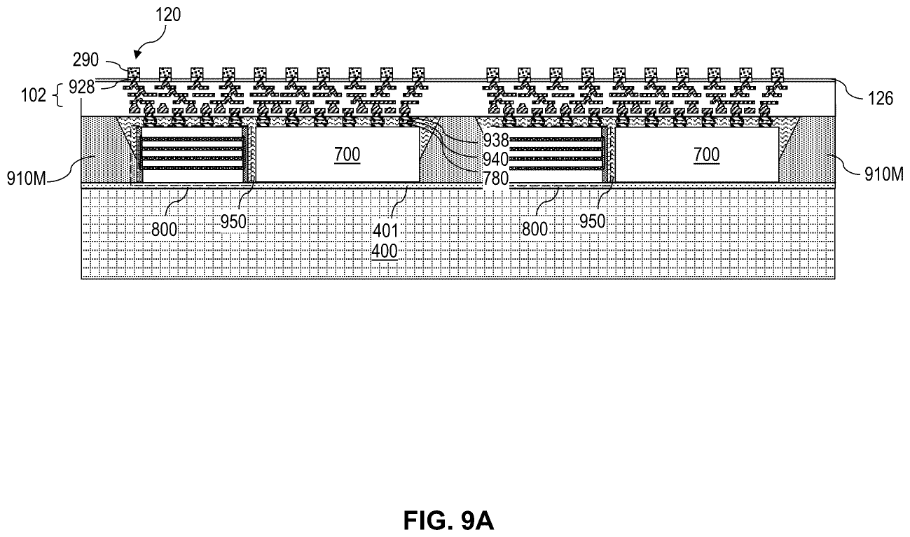

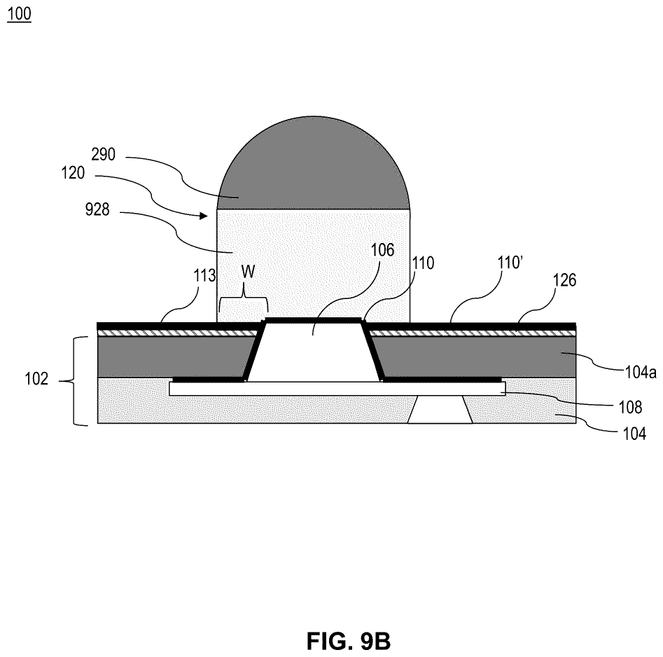

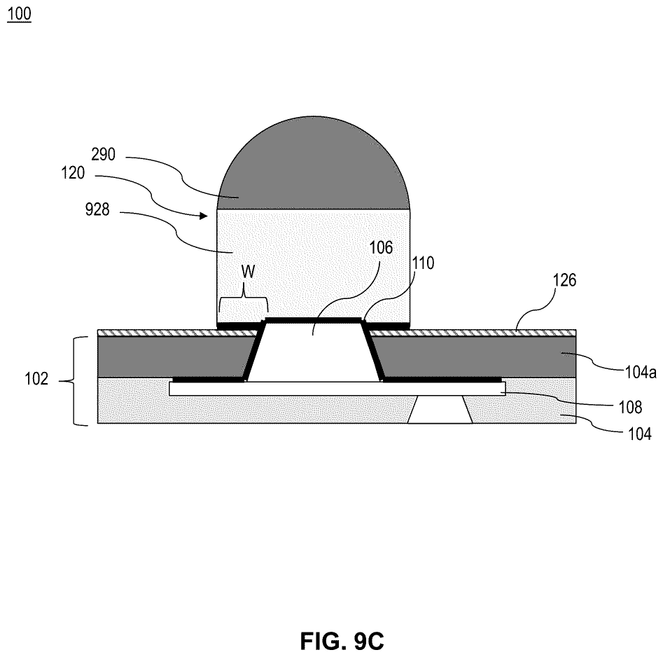

Referring to FIG. 9A, surface mount connectors 120 may be formed above the dielectric layer 126 with the metallic liner 110 (shown in FIGS. 9B and 9C) located between the dielectric layer 126 and the surface mount connectors 120. In some embodiments, the surface mount connectors 120 may include RDL bonding pads 928 and second solder material portions 290 may be formed by depositing and patterning a stack of at least one metallic material that may function as metallic bumps and a solder material layer. The metallic fill material for the RDL bonding pads 928 may include copper. Other suitable materials are within the contemplated scope of disclosure. The thickness of the RDL bonding pads 928 may be in a range from 5 microns to 100 microns, although lesser or greater thicknesses may also be used. The RDL bonding pads 928 and the second solder material portions 290 may have horizontal cross-sectional shapes of rectangles, rounded rectangles, or circles. Other suitable shapes are within the contemplated scope of disclosure. In embodiments in which the RDL bonding pads 928 are formed as C4 (controlled collapse chip connection) pads, the thickness of the RDL bonding pads 928 may be in a range from 5 microns to 50 microns, although lesser or greater thicknesses may also be used. In some embodiments, the RDL bonding pads 928 may be, or include, underbump metallization (UBM) structures. The configurations of the RDL bonding pads 928 are not limited to be fan-out structures. Alternatively, the RDL bonding pads 928 may be configured for microbump bonding (i.e., C2 bonding), and may have a thickness in a range from 30 microns to 100 microns, although lesser or greater thicknesses may also be used. In such an embodiment, the RDL bonding pads 928 may be formed as an array of microbumps (such as copper pillars) having a lateral dimension in a range from 10 microns to 25 microns, and having a pitch in a range from 20 microns to 50 microns.

The RDL bonding pads 928 and the second solder material portions 290 may be formed on the opposite side of the EMC matrix 910M and the two-dimensional array of sets of semiconductor dies (700, 800) relative to the interposer layer. The interposer layer includes a three-dimensional array of RDL 102. RDL 102 may be located within a respective unit area UA. The RDL 102 may include redistribution dielectric layers 104, vias 106/107 and metal traces 108 embedded in the redistribution dielectric layers 104, and RDL bonding pads 928. The RDL bonding pads 928 may be located on an opposite side of the redistribution-side bonding structures 938 relative to the redistribution dielectric layers 104, and may be electrically connected to a respective one of the redistribution-side bonding structures 938.

Turning to FIG. 9B, a surface connector 120 may be formed above the via 106. In an embodiment, the surface mount connector 120 is a C4 bump, surface mount pad, BGA, LGA, or other appropriate surface mount connector. In the embodiment in which the surface mount connector 120 is a C4 bump, a bonding pads 928 120 formed of solder is placed above the via 106. The solder material may be heated to a temperature above the melting point of the solder material and undergo a reflow process to form a solder ball 290 above the bonding pads 928.

In some embodiments, the connector 120 extends beyond the via 106 to cover a portion of the metallic liner 110′ above the dielectric layer 126. As shown in FIG. 2G, a width W of the surface mount connector that extends beyond the via 106 may be between about 0 μm to about 300 μm, or about 50 μm to about 200 μm, or about 100 μm to about 150 μm, or combinations between thereof. In some embodiments, the width W may be optimized so that the surface mount connector 120 corresponds to other package elements.

Turning to FIG. 9C, the metallic liner 110 may be etched back to remove portions of the metallic liner 110 located above the dielectric layer 126 but outside the perimeter established under the surface mount connector 120. In an alternative embodiment, the metallic liner 110 may be removed using other removal methods such as CMP. In other words, the metallic liner 110 above the via 106 and width W above the dielectric layer 126 remains after the etch back process. The resulting semiconductor structure 100 includes a substantially smooth surface above the passivation layer 104 in the RDL 102 due to the dielectric layer 126.

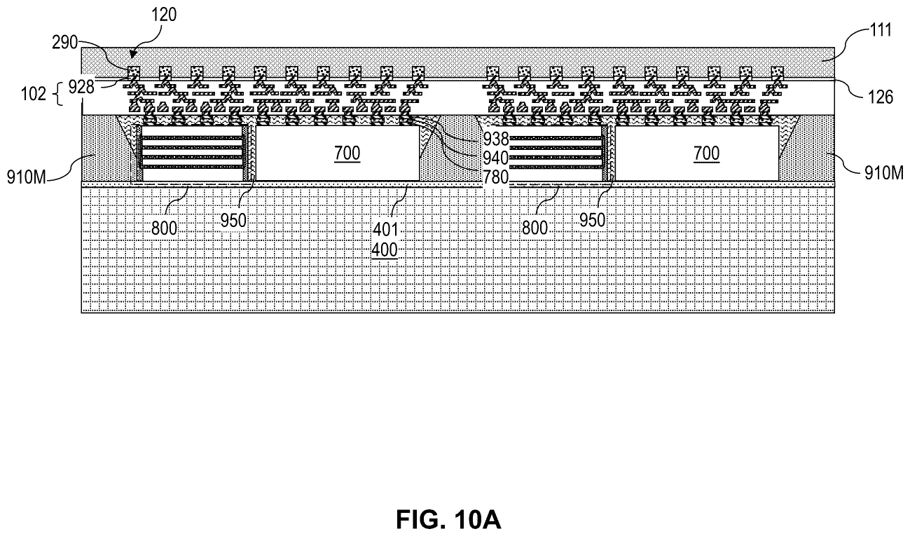

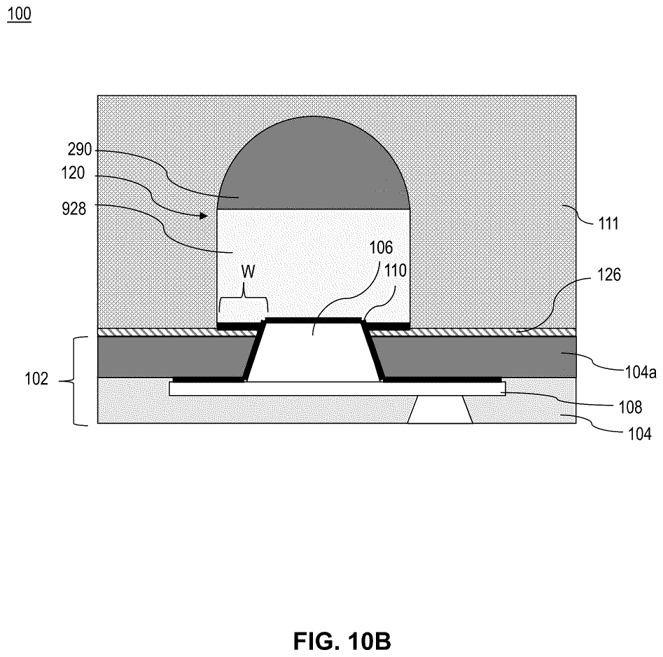

Referring to FIGS. 10A and 10B, a backgrind tape 111 may be applied above the dielectric layer 126 to surround and protect the surface mount connectors 120 during a wafer backgrinding process. In the wafer backgrinding process the wafer thickness is reduced to enable stacking and high-density packaging. The backgrind tape 111 may provide surface protection to the surface mount connectors 120 during the backgrinding process. Additionally, the backgrind tape 111 may prevent contamination from grinding fluid, debris, and other contaminates during the wafter backgrinding process.

The backgrind tape 111 may be a UV curable backgrind tape, non-UV backgrind tape, or other appropriate types of backgrind tape. In an embodiment, the UV curable backgrind tape 111 is applied to the surface. The UV curable tape may undergo a UV curing reaction in response to being exposed to UV irradiation. In particular, UV curable backgrind tape may provide enhanced protection during the backgrind process by ensuring minimal contamination transfer. In contrast, non-UV tape may provide reliable protection without the UV curing process. In particular, non-UV tape may prevent water penetration, minimize breakage, and maintain topography absorption.

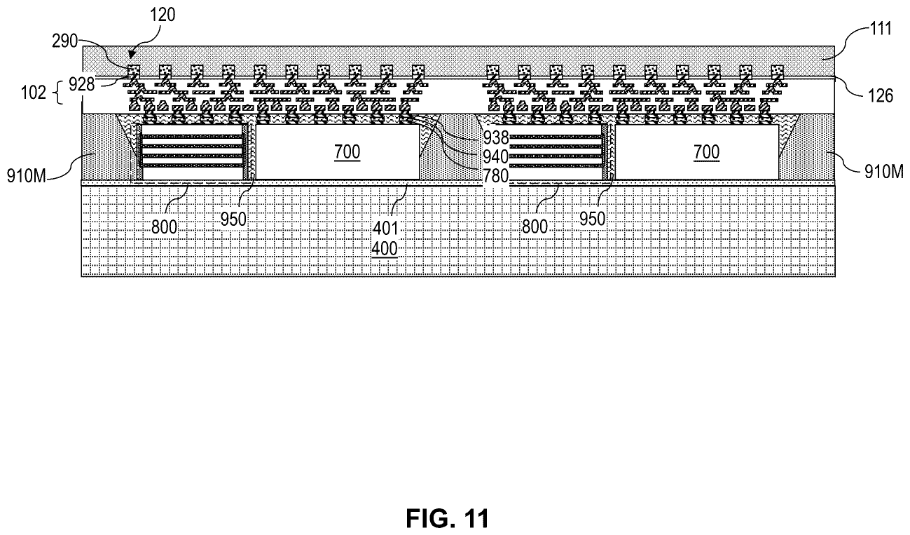

Referring to FIG. 11, the carrier wafer 400 may undergo a thinning process. In some embodiments, the wafer 400 thinning process may include mechanical grinding, chemical mechanical polishing (CMP), wet etching, atmospheric downstream plasma (ADP) dry chemical etching, or other appropriate thinning processes. Mechanical grinding may include a two-step process including a coarse grinding to remove a majority of the material followed by a fine grinding process that reduces surface roughness and removing any damaged layers. CMP includes applying a chemical composition followed by a polishing process to achieve a flat surface. While CMP is slower than mechanical polishing, it may provide better planarization. Wet etching includes using a chemical solution to etch away the material. ADP dry chemical etching includes using a plasma to etch away the material to offer precise control over the thinning process.

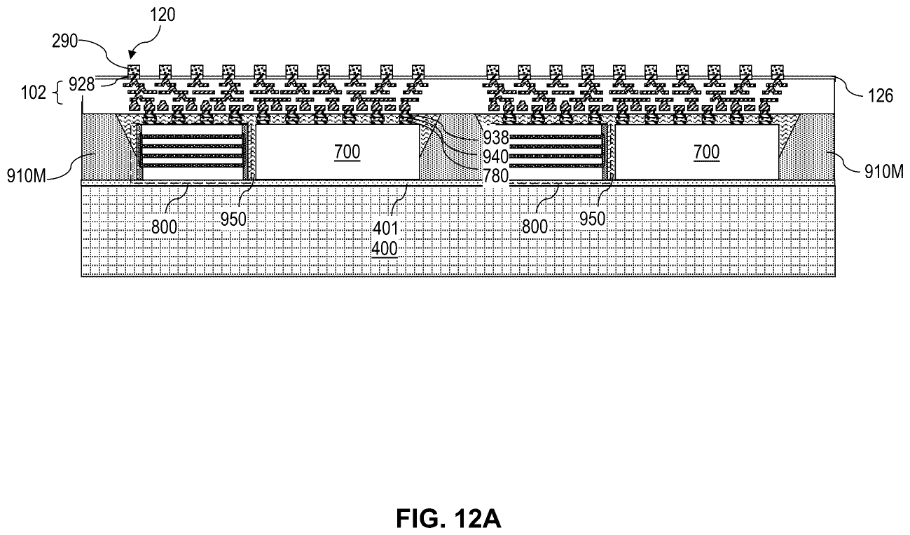

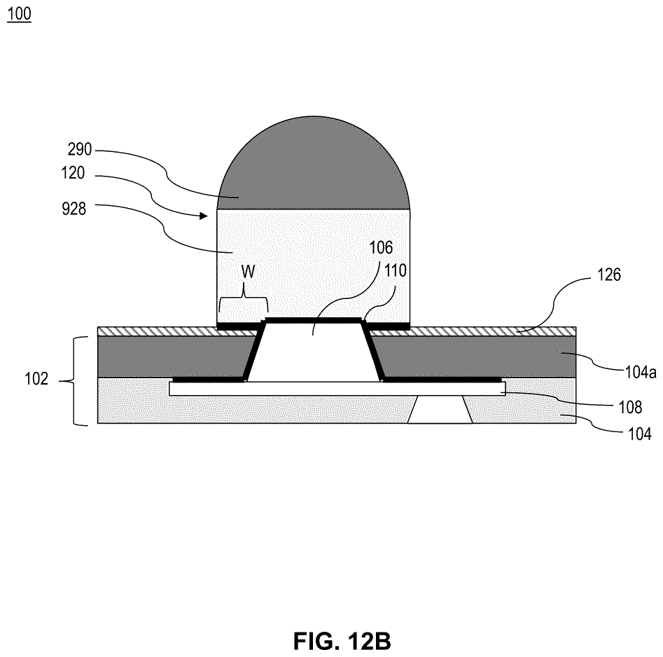

Turning to FIGS. 12A and 12B, the backgrind tape 111 may be removed. In an embodiment, the UV curable tape may undergo a polymerization reaction under UV irradiation which hardens the UV curable tape and causes the UV curable tape to lose adhesive strength resulting in an easier peel. In an alternative embodiment, the non-UV tape may be removed by mechanically peeling or by a solvent. Because the dielectric layer 126 provides a pristine layer that prevents the residue from attaching to the top surface of the dielectric layer 126, the dielectric layer 126 prevents unwanted de-taping or underfill delamination. As shown, substantially no tape residue is left on the top surface of the dielectric layer 126 due to the dielectric layer 126 being formed of a material that prevents tape residue from attaching to the surface.

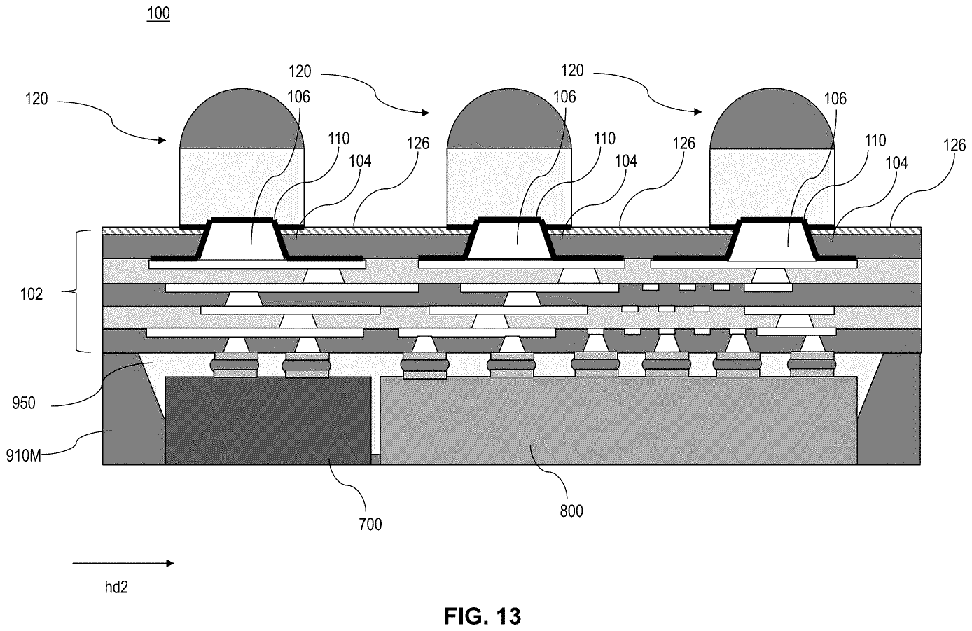

Turning to FIG. 13, a cross-sectional view of an example schematic of a semiconductor structure 100 is illustrated. In some embodiments, the semiconductor structure 100 includes an RDL 102, semiconductor die (700, 800) connected to the RDL 102 through connectors 114 surrounded by an underfill 950 and mold 910M, a dielectric layer 126 located above the RDL 102 and surface mount connectors 120 located above the RDL 102 with a metallic liner 110 located between the surface mount connectors and the dielectric layer 126.

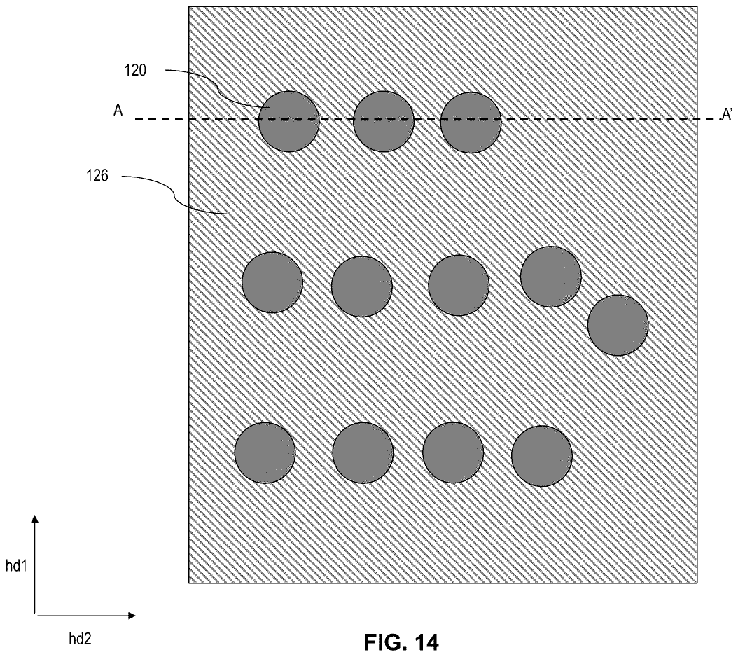

In some embodiments, the semiconductor die (700, 800) may be the same type of component (e.g., HBM components) or different types of components (e.g., HBM component, SoC component, and I/O component). Further, each semiconductor die (700, 800) may be connected to the RDL 102 by the same number of connectors 114 or varying number of connectors 114, as shown in FIG. 14A.

Referring now to FIG. 14 that illustrates a top view of the semiconductor structure 100. The cut line AA′ illustrates the location of the cross-section view shown in FIGS. 1 and 13. As shown, the semiconductor structure 100 includes multiple surface mount connectors 120 in a two-dimensional (2D) array with a dielectric layer 126 surrounding the top surface of the semiconductor structure 100. As shown, the dielectric layer 126 prevents tape residue thereby providing a smooth and pristine layer even after application of a backgrind tape.

The following discussion now refers to a number of methods and method acts. Although the method steps are discussed in specific orders or are illustrated in a flow chart as being performed in a particular order, no order is required unless expressly stated or required because a step is dependent on another step being completed prior to the step being performed.

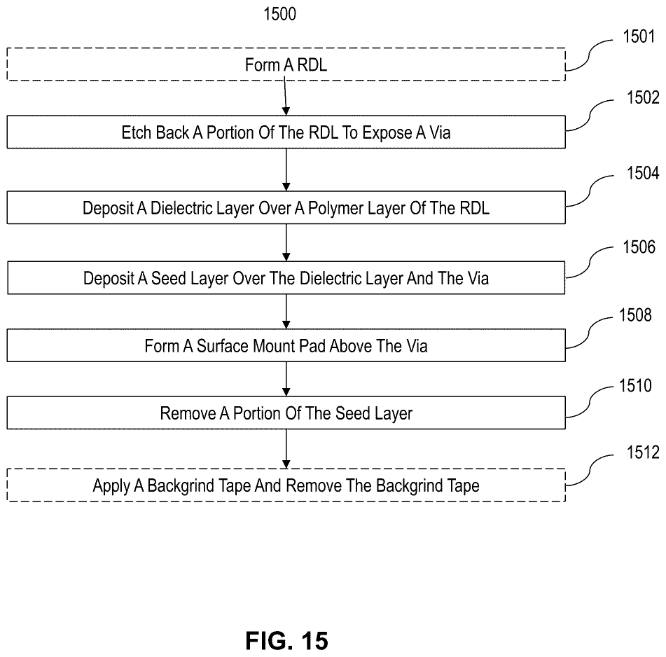

Embodiments are now described in connection with FIG. 15, which illustrates a flow diagram of example method 1500 for forming a semiconductor structure 100, according to an embodiment of the present disclosure. In an embodiment, step 1502 comprises etching back a portion of a RDL to expose a via. Referring to FIGS. 1, 7B, and 13, in step 1502 of method 1500, the top passivation layer 104 of the RDL 102 is etched back using a dry etch, wet etch, or other appropriate etching method. Additionally, the metallic liner 110 above the top of the via 106 is similarly etched back. In an embodiment, etching back the portion of the RDL 102 removes a portion of the passivation layer 104 and a metallic liner 110 located above the via 106.

Optionally, the method 1500 further includes a step 1501 that forms the RDL 102. The via 106 may be formed by etching a cavity within a passivation layer 104 within a passivation layer 104a. The passivation layer 104 may be formed of polyimide or other appropriate dielectric material. In some embodiments, the cavity is etched using a dry etching process, wet etching process, or other appropriate etching process. The cavity may have a trapezoidal shape, rectangular shape, or other appropriate shape. A metallic liner 110 may be deposited within the cavity. In an embodiment, the metallic liner 110 is formed of a copper metallic liner and a titanium adhesion layer. The metallic liner 110 may be deposited using AVD, ALD, CVD, low temperature CVD, or other appropriate deposition methods. Subsequently, the cavity is filled with a conductive material to form the via 106. In some embodiments, filling the cavity includes growing the conductive material within the cavity. For example, the method may include growing a conductive material within the cavity to form the via 106. A metal trace 108 may be formed above the via 106. The metal trace 108 may also be formed of a conductive material and may include the metallic liner 110. In an embodiment, the conductive material is copper, silver, gold, tungsten, or other appropriate conductive material. This process may repeat until a desired number of dielectric layers 104/104a form a complete RDL 102 with a via 106/107 and/or metal trace 108 is formed in each dielectric layer 104/104a.

In an embodiment, step 1504 comprises depositing a dielectric layer 126 over a passivation layer of the RDL. Referring to FIGS. 1, 8A, 8B, and 13, in step 1504 of method 1500, the dielectric layer 126 is formed of the etched back passivation layer 104 in the RDL 102. In some embodiments, the dielectric layer 126 is deposited using CVD, AVD, ALD, low temperature CVD, or other appropriate deposition methods. The dielectric layer 126 may be formed of a material that prevents tape residue from sticking to the surface, such as silicon nitride, silicone oxynitride, or other appropriate dielectric material. The dielectric layer 126 may be deposited above the passivation layer 104 until between about 0.01 μm and 5 μm, or between about 0.05 and about 3 μm is deposited. The dielectric layer 126 may provide a smooth surface above the passivation layer 104 where the passivation layer 104 may be unsmooth due to the etching process.

In an embodiment, step 1506 comprises depositing a metallic liner over the dielectric layer 126 and the via 106. Referring to FIGS. 1, 8C, and 13, in step 1506 of method 1500, the metallic liner 110′ is deposited using AVD, CVD, ALD, low temperature CVD, or other appropriate deposition methods. The metallic liner 110′ may be formed of a copper seed and a titanium adhesion layer. The metallic liner 110′ may be deposited above the dielectric layer 126 and the via 106.

In an embodiment, step 1508 comprises forming a surface mount connector 120 above the via 106. Referring to FIGS. 1, 9A, 9B, and 13, in step 1508 of method 1500, the surface mount connector 120 is formed above the via 106. In an embodiment, the surface mount connector 120 is a C4 bump that includes a bonding pads 928 and a bump 290. The bonding pads 928 and the bump 290 may be formed of a solder material, such as a tin-lead alloy. The surface mount connector 120 may be formed by depositing a solder material above the RDL 102. A photoresist layer and a mask may be used to define the desired bump. The exposed photoresist may be developed leaving behind a pattern for the bump 290. Extra solder material may be etched away, using a dry etching process or a wet etching process, leaving the bonding pads 928 and bump 290 structures. The solder material may further be heated to a temperature above the solder's melting point to cause a reflow process resulting in the collapsing and forming of the C4 bump 120.

In an embodiment, step 1510 comprises removing a portion of the metallic liner 110. Referring to FIGS. 1, 9C, and 13, in step 1510 of method 1500, the metallic liner 110′ may removed from a portion of the dielectric layer 126 leaving behind the metallic liner 110 located between the RDL 102 and the surface mount connector 120. The metallic liner 110′ may be removed using an etching process, such as dry etching or wet etching, a grinding process, or other appropriate removal methods. The resulting semiconductor structure 100 includes surface mount connectors 120 and a substantially smooth, pristine dielectric layer 126. The dielectric layer 126 may prevent tape residue from attaching to the surface.

Optionally, in an embodiment, step 1512 comprises applying a backgrind tape above the dielectric layer 126 surrounding the surface mount connectors 120 and subsequent to a wafer thinning process, removing the backgrind tape. Referring to FIGS. 1, 10A-13, in step 1512 of method 1500 the backgrind tape 111 is applied to above the dielectric layer 126 surrounding the surface mount connectors 120. In an embodiment, when the backgrind tape 111 is removed, the smooth, pristine dielectric layer 126 may be formed of a material that prevents tape residue from being left behind on the surface. Therefore, after the backgrind tape 111 removal, the dielectric surface 126 is free from tape residue as shown in FIG. 14.

Referring to all drawings and according to various embodiments of the present disclosure, a semiconductor structure 100 includes a redistribution layer 102, where the redistribution layer 102 includes a passivation layer 104a and a via 106; a surface mount connector 120 located above the via 106; a dielectric layer 126 located between the passivation layer 104 and the surface mount connector 120, wherein the dielectric layer 126 is formed of a material that inhibits a tape residue from attaching to a top surface of the dielectric layer 126; and a metallic liner 110′ located between the surface mount connector 120 and the redistribution layer 102.

In some embodiments, the via 106 includes a via metallic liner 110, an outside perimeter of the via 106. In some embodiments, the metallic liner 110 is formed of copper and titanium. In some embodiments, the dielectric layer 126 is formed of silicon nitride or silicon oxynitride. In some embodiments, the surface mount connector 120 is a C4 bump. In some embodiments, the surface mount connector 120 is a ball grid array. In some embodiments, a thickness of the dielectric layer 126 is between about 0.05 μm and about 3 μm. In some embodiments, a side width W of the surface mount connector is located above a portion of the dielectric layer 102 and the side width W is at most 200 μm. In some embodiments, the semiconductor structure 100 further includes a semiconductor die (700, 800) connected to the redistribution layer 102 by a connector 114. In some embodiments, the semiconductor structure 100 further includes an underfill 950 surrounding the semiconductor die (700, 800) and the connector 114 and a mold 910M surrounding the underfill 950. In some embodiments, the top surface of the dielectric layer 126 is substantially smooth.

In an alternative embodiment, a method 1500 of forming a semiconductor structure 100 includes etching back a portion of a redistribution layer 102 to expose a via 106; depositing a dielectric layer 126 over a passivation layer 104 of the redistribution layer 102; depositing a metallic liner 110 over the dielectric layer 126 and the via 106; forming a surface mount connector 120 above the via 106; removing a portion of the metallic liner 110; applying a backgrind tape 111 above a top surface of the dielectric layer 126 and surrounding the surface mount connector 120; and removing the backgrind tape 111, wherein the dielectric layer 126 is formed of a material that prevents any tape residue attaching to the top surface of the dielectric layer 126.

In some embodiments, the method further includes smoothing a top surface of the dielectric layer 126 to form a substantially smooth surface. In some embodiments, the method 1500 further includes forming the redistribution layer 102. In some embodiments, forming the redistribution layer 102 further comprises: etching a cavity within the passivation layer 104; depositing a metallic liner 110 in the cavity; filling the cavity with a conductive material to form the via 106; and forming a metal trace 108 above the cavity. In some embodiments, forming the surface mount connector 120 further comprises forming the surface mount connector 120 above a portion of the dielectric layer 126. In some embodiments, the portion of the dielectric layer 126 has a width W of at most of 200 μm on each side of the via 106. In some embodiments, removing a portion of the metallic liner 110′ leaves behind a remaining portion of the metallic liner 110, wherein the remaining portion of the metallic liner 110 is located between the dielectric layer 110 and the surface mount connector 120. In some embodiments, the dielectric layer 126 is deposited until a height of the dielectric layer 126 is between about 0.05 μm and about 3 μm. In some embodiments, the dielectric layer 126 is deposited by low temperature chemical vapor deposition and is formed of silicon nitride or silicon oxynitride. In some embodiments, etching back the portion of the redistribution layer 102 removes a portion of the passivation layer 126 and a via metallic liner 110 located above the via 106.

In an alternative embodiment, a method 1500 of forming a semiconductor structure 100, includes etching back a portion of a RDL 102 including a passivation layer 104 and a metallic liner 110 to expose a via 106; depositing a dielectric layer 126 over the passivation layer 104 of the redistribution layer 102, wherein the dielectric layer 126 is formed of a material that prevents a tape residue from attaching to a top surface of the dielectric layer 126 depositing a metallic liner 110 over the dielectric layer 126 and the via 106; forming a C4 bump 120 above the via 106; and removing a portion of the metallic liner 110.

In some embodiments, forming the surface mount connector 120 further includes forming the C4 bump 120 above a portion of the dielectric layer 126 where the portion of the dielectric layer 126 has a width W of at most of 200 μm on each side of the via 106. In some embodiments, the dielectric layer 126 is deposited until a thickness of the dielectric layer 126 is between about 0.05 μm and about 3 μm and the dielectric layer 126 is substantially smooth. In some embodiments, the method further includes applying a backgrind tape 111 above the top surface of the dielectric layer 126 and surrounding the surface mount connector 124; and removing the backgrind tape 111 from the top surface of the dielectric layer 126, wherein the dielectric layer 126 prevents a backgrind tape residue from attaching to the top surface of the dielectric layer 126. In some embodiments, wherein depositing the dielectric layer 126 over the passivation layer 104 of the redistribution layer 102 includes performing a low temperature chemical vapor deposition process, and wherein the dielectric layer 126 includes silicon nitride or silicon oxynitride.

The various embodiments disclosed herein may provide various advantages and improvements. For example, various embodiments disclosed herein may provide a smooth passivation layer by the addition of a dielectric layer on the surface of the redistribution layer. In various embodiments, the dielectric layer is added on the passivation layer of the redistribution layer after a wafer thinning or dry etching process that uses a backgrind tape. Therefore, any backgrind tape residue left on the passivation layer is removed during formation of the dielectric layer or covered by the dielectric layer. By providing a clean passivation layer post dry etching, various embodiments reduce problems due to tape residue such as the de-taping of a glue layer during CoW die singulation or underfill delamination.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a redistribution layer, wherein the redistribution layer includes a passivation layer and a via within the passivation layer;
a surface mount connector located above the via;
a dielectric layer located between the passivation layer and the surface mount connector the passivation layer, wherein the dielectric layer is formed of a material including at least silicon and nitrogen; and
a metallic liner located between the surface mount connector and the redistribution layer.

2. The semiconductor structure of claim 1, wherein the via includes a via metallic liner.

3. The semiconductor structure of claim 1, wherein the dielectric layer is formed of silicon nitride or silicon oxynitride.

4. The semiconductor structure of claim 1, wherein a thickness of the dielectric layer is between about 0.05 μm and about 3 μm.

5. The semiconductor structure of claim 1, wherein a side width of the surface mount connector is located above a portion of the dielectric layer and the side width is at most 200 μm.

6. The semiconductor structure of claim 1, wherein the top surface of the dielectric layer is substantially smooth.

7. A method of forming a semiconductor structure, comprising:
etching back a portion of a redistribution layer to expose a via;
depositing a dielectric layer over a passivation layer of the redistribution layer;
depositing a metallic liner over the dielectric layer and the via;
forming a surface mount connector above the via;
removing a portion of the metallic liner;
applying a backgrind tape above a top surface of the dielectric layer and surrounding the surface mount connector; and
removing the backgrind tape, wherein the dielectric layer is substantially free of tape residue on the top surface of the dielectric layer.

8. The method of claim 7, further comprising smoothing a top surface of the dielectric layer to form a substantially smooth surface.

9. The method of claim 7, wherein forming the surface mount connector further comprises forming the surface mount connector above a portion of the dielectric layer, wherein the portion of the dielectric layer has a width of at most of 200 μm on each side of the via.

10. The method of claim 9, wherein removing a portion of the metallic liner leaves behind a remaining portion of the metallic liner, wherein the remaining portion of the metallic liner is located between the dielectric layer and the surface mount connector.

11. The method of claim 7, wherein the dielectric layer is deposited until a thickness of the dielectric layer is between about 0.05 μm and about 3 μm.

12. The method of claim 7, wherein the dielectric layer is deposited by low temperature chemical vapor deposition and is formed of silicon nitride or silicon oxynitride.

13. The method of claim 7, wherein etching back the portion of the redistribution layer removes a portion of the passivation layer and a via metallic liner.

14. The method of claim 13, wherein a top portion of the via metallic liner is removed.

15. The method of claim 13, wherein a top portion and a side portion of the via metallic liner is removed.

16. A method of forming a semiconductor structure, comprising:
etching back a portion of a redistribution layer including a passivation layer and a via metallic liner to expose a via;
depositing a dielectric layer over the passivation layer of the redistribution layer, wherein the dielectric layer is formed of at least one of silicon nitride or silicon oxynitride ;
depositing a metallic liner over the dielectric layer and the via;
forming a surface mount connector that includes a C4 bump above the via; and
removing a portion of the metallic liner.

17. The method of claim 16, wherein forming the surface mount connector further comprises forming the C4 bump above a portion of the dielectric layer, wherein the portion of the dielectric layer has a width of at most of 200 μm on each side of the via.

18. The method of claim 16, wherein the dielectric layer is deposited until a thickness of the dielectric layer is between about 0.05 μm and about 3 μm and the dielectric layer is substantially smooth.

19. The method of claim 16, further comprising:
applying a backgrind tape above the top surface of the dielectric layer and surrounding the surface mount connector; and
removing the backgrind tape from the top surface of the dielectric layer, wherein the dielectric layer prevents a backgrind tape residue from attaching to the top surface of the dielectric layer.

20. The method of claim 16, wherein depositing the dielectric layer over the passivation layer of the redistribution layer comprises:
performing a low temperature chemical vapor deposition process, and wherein the dielectric layer comprises silicon nitride or silicon oxynitride.
